(19) United States
(12) Patent Application Publication
(10) Pub. No.: US 2010/0037007 A1
(43) Pub. Date: Feb. 11, 2010

(54) NONVOLATILE SEMICONDUCTOR MEMORY DEVICE

(75) Inventors: TAKUYA FUTATSUYAMA, YOKOHAMA-SHI (JP); NAOYA TOKIWA, FUJISAWA-SHI (JP); TOSHIAKI EDAHIRO, YOKOHAMA-SHI (JP); YOSHIHIKO SHINDO, FUJISAWA-SHI (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, TOKYO (JP)

(21) Appl. No.: 12/534,336

(22) Filed: Aug. 3, 2009

(30) Foreign Application Priority Data
Aug. 5, 2008 (JP) 2008-202428

(51) Int. Cl. G06F 12/00; G11C 7/00; G06F 12/02

(52) U.S. Cl. 711/103; 365/189.14; 711/E12.001; 711/E12.008

(57) ABSTRACT

A nonvolatile semiconductor memory device includes a memory cell array in which memory cells having an electrically rewritable charge accumulation layer are arranged, a data writing/reading circuit that writes/reads data to/from the memory cell array in units of pages, a write state information storage circuit for nonvolatile storage of write state information indicating a data write state to the memory cell array by the data writing/reading circuit, and a control circuit that controls the data writing/reading circuit based on an access page address indicating a page from which data is about to be read by the data writing/reading circuit and write state information stored in the write state information storage circuit.

### CROSS-REFERENCE TO RELATED APPLICATIONS

This application is based upon and claims the benefit of priority from the prior Japanese Patent Application No. 2008-202428, filed on Aug. 5, 2008, the entire contents of which are incorporated herein by reference.

### BACKGROUND OF THE INVENTION

1. Field of the Invention

The present invention relates to an electrically rewritable nonvolatile semiconductor memory device, and in particular, relates to a nonvolatile semiconductor memory having a data read method appropriate for a flash memory having microscopic cells.

2. Description of the Related Art

Many kinds of currently known EEPROM use memory cells of type that accumulates charges in a charge accumulation layer (for example, a floating gate). In a NAND type flash memory, which is one type thereof, data is rewritten by using an FN tunnel current for both write and erase operations. In recent years, multi-bit (level) storage technology that stores two bits of data or more in one memory cell is introduced so that the storage capacity can be doubled or more with physically the same cell size.

However, when memory cells become denser with feature size scaling of NAND type flash memories, the distance between memory cells decreases and interference between adjacent cells increases. This is because scaling in the longitudinal direction is more difficult to implement when compared with contraction by scaling in the lateral direction of a cell array.

More specifically, a floating gate of a memory cell is formed between a control gate (word line) and a substrate (channel) via insulating film. If the cell becomes finer, the capacity between a floating gate of one memory cell and that of an adjacent memory cell increases relative to that between a floating gate and a control gate and substrate. Inter-cell interference based on the capacity between floating gates of adjacent cells has an influence that the threshold of memory cells to which data has been written is shifted by fluctuations in threshold of memory cells to which data is written later. As a result, the threshold distribution spreads and data reading reliability is degraded.

To improve data reading reliability, data may be written in such a way that the threshold distribution becomes as narrow as possible. In this case, however, there is a problem that the write time increases because a fine verification operation will be needed. Or, increasing a margin between threshold distributions by raising the threshold of each piece of data may be considered. In this case, however, there is a problem that stress on memory cells increases because the highest threshold distribution elevated to the high voltage side and it becomes necessary to increase a pass voltage Vpass and a read voltage Vread of non-selected memory cells.

Thus, a data write method by which data is written in such a way that the threshold distribution is allowed to spread when the first page is written, but the threshold distribution is made narrower when the last page is written is proposed (Patent Document 1: Japanese Patent Application Laid-Open No. 2005-243205).

On the other hand, a nonvolatile semiconductor memory device of DLA (Direct Look Ahead) method is proposed as a method of compensating for an influence of shift of the threshold voltage due to inter-cell interference in a read operation from memory cells (Patent Document 2: Japanese Patent Application Laid-Open No. 2004-326866). According to this method, before reading from a memory cell, data in adjacent memory cells to which data is written after the memory cell is read in advance and reading conditions for the memory cell from which data is about to be read are decided in accordance with readout results to correct the threshold of the memory cell from which data is about to be read.

However, in a nonvolatile semiconductor memory device of DLA method, an overall readout time increases because it becomes necessary to read data from a plurality of memory cells to read data from one memory cell. Moreover, the read voltage Vread is more frequently applied to memory cells, posing a problem of increasing stress applied to memory cells.

### SUMMARY OF THE INVENTION

A nonvolatile semiconductor memory device according to an aspect of the present invention includes a memory cell array in which memory cells having an electrically rewritable charge accumulation layer are arranged, a data writing/reading circuit that writes/reads data to/from the memory cell array in units of pages, a write state information storage circuit for nonvolatile storage of write state information indicating a data write state to the memory cell array by the data writing/reading circuit, and a control circuit that controls the data writing/reading circuit based on an access page address indicating a page from which data is about to be read by the data writing/reading circuit and write state information stored in the write state information storage circuit.

A nonvolatile semiconductor memory device according to another aspect of the present invention includes a memory cell array in which memory cells having an electrically rewritable charge accumulation layer are arranged, a data writing/reading circuit that writes/reads data to/from the memory cell array in units of pages, a write state information storage circuit for storing write state information indicating a data write state to the memory cell array by the data writing/reading circuit, and a control circuit that references the write state information stored in the write state information storage circuit and, if an access page about to be read is a page to which data has been written and the data in the page is estimated to be affected by writing to adjacent pages after the data being written to the page, controls the data writing/reading circuit so that the access page is read after data of the adjacent pages being read.

A nonvolatile semiconductor memory device according to still another aspect of the present invention includes a memory cell array in which memory cells having an electrically rewritable charge accumulation layer are arranged, a data writing/reading circuit that writes/reads data to/from the memory cell array in units of pages, a write state information storage circuit for storing write state information indicating a data write state to the memory cell array by the data writing/reading circuit, and a control circuit that references the write state information stored in the write state information storage circuit and, if an access page about to be read is in an erase state, outputs data indicating the erase state as read data without the access page being accessed by the data writing/reading circuit.

### BRIEF DESCRIPTION OF THE DRAWINGS

FIG. 1 is a diagram showing a configuration of a flash memory according to a first embodiment of the present invention.

FIG. 2 is a diagram showing the configuration of a memory cell array of the flash memory.

FIG. 3 is a schematic connection diagram of sense amplifiers and bit lines of the flash memory.

FIG. 4 is a diagram showing a data distribution example of the flash memory.

FIG. 5 is a diagram showing a data write order of the flash memory.

FIG. 6 is a diagram showing a flow of data read operations of the flash memory.

FIG. 7 is a diagram showing Scheme A to estimate a data write state from a last page address of the flash memory.

FIG. 8 is a diagram generalizing the Scheme A.

FIG. 9 is a diagram showing the flow of Scheme C to determine a word line and a level of hierarchy of a reading page from an access page address of the flash memory.

FIG. 10A is a diagram showing Scheme D to decide a read method from the access page address and the last page address of the flash memory.

FIG. 10B is a diagram showing the Scheme D to decide the read method from the access page address and the last page address of the flash memory.

FIG. 10C is a diagram showing the Scheme D to decide the read method from the access page address and the last page address of the flash memory.

FIG. 10D is a diagram showing the Scheme D to decide the read method from the access page address and the last page address of the flash memory.

FIG. 10E is a diagram showing the Scheme D to decide the read method from the access page address and the last page address of the flash memory.

FIG. 10F is a diagram showing the Scheme D to decide the read method from the access page address and the last page address of the flash memory.

FIG. 11 is a schematic connection diagram of sense amplifiers and bit lines of a flash memory according to a second embodiment of the present invention.

FIG. 12 is a diagram showing the data write order of the flash memory.

FIG. 13 is a diagram showing the Scheme A to estimate the data write state from the last page address of the flash memory.

FIG. 14 is a diagram generalizing the Scheme A.

FIG. 15 is a diagram showing the flow of Scheme C to determine the word line and the level of hierarchy of a reading page from the access page address of the flash memory.

FIG. 16 is a diagram showing a data distribution example of a flash memory according to a third embodiment of the present invention.

FIG. 17 is a diagram showing the data write order of the flash memory.

FIG. 18 is a diagram showing the Scheme A to estimate the data write state from the last page address of the flash memory.

FIG. 19 is a diagram generalizing the Scheme A.

FIG. 20 is a diagram showing the flow of Scheme C to determine the word line and the level of hierarchy of a reading page from the access page address of the flash memory.

FIG. 21A is a diagram showing the Scheme D to decide the read method from the access page address and the last page address of the flash memory.

FIG. 21B is a diagram showing the Scheme D to decide the read method from the access page address and the last page address of the flash memory.

FIG. 21C is a diagram showing the Scheme D to decide the read method from the access page address and the last page address of the flash memory.

FIG. 21D is a diagram showing the Scheme D to decide the read method from the access page address and the last page address of the flash memory.

FIG. 21E is a diagram showing the Scheme D to decide the read method from the access page address and the last page address of the flash memory.

FIG. 21F is a diagram showing the Scheme D to decide the read method from the access page address and the last page address of the flash memory.

FIG. 21G is a diagram showing the Scheme D to decide the read method from the access page address and the last page address of the flash memory.

FIG. 21H is a diagram showing the Scheme D to decide the read method from the access page address and the last page address of the flash memory.

FIG. 21I is a diagram showing the Scheme D to decide the read method from the access page address and the last page address of the flash memory.

FIG. 21J is a diagram showing the Scheme D to decide the read method from the access page address and the last page address of the flash memory.

FIG. 21K is a diagram showing the Scheme D to decide the read method from the access page address and the last page address of the flash memory.

FIG. 21L is a diagram showing the Scheme D to decide the read method from the access page address and the last page address of the flash memory.

FIG. 22 is a diagram showing the data write order of a flash memory according to a fourth embodiment of the present invention.

FIG. 23 is a diagram showing the Scheme A to estimate the data write state from the last page address of the flash memory.

FIG. 24 is a diagram generalizing the Scheme A.

FIG. 25 is a diagram showing the flow of Scheme C to determine the word line and the level of hierarchy of a reading page from the access page address of the flash memory.

FIG. 26A is a diagram showing the Scheme D to decide the read method from the access page address and the last page address of the flash memory.

FIG. 26B is a diagram showing the Scheme D to decide the read method from the access page address and the last page address of the flash memory.

FIG. 26C is a diagram showing the Scheme D to decide the read method from the access page address and the last page address of the flash memory.

FIG. 26D is a diagram showing the Scheme D to decide the read method from the access page address and the last page address of the flash memory.

FIG. 26E is a diagram showing the Scheme D to decide the read method from the access page address and the last page address of the flash memory.

FIG. 26F is a diagram showing the Scheme D to decide the read method from the access page address and the last page address of the flash memory.

FIG. 26G is a diagram showing the Scheme D to decide the read method from the access page address and the last page address of the flash memory.

FIG. 26H is a diagram showing the Scheme D to decide the read method from the access page address and the last page address of the flash memory.

FIG. 26I is a diagram showing the Scheme D to decide the read method from the access page address and the last page address of the flash memory.

### DETAILED DESCRIPTION OF THE EMBODIMENTS

Embodiments of the present invention will be described below with reference to drawings

### First Embodiment

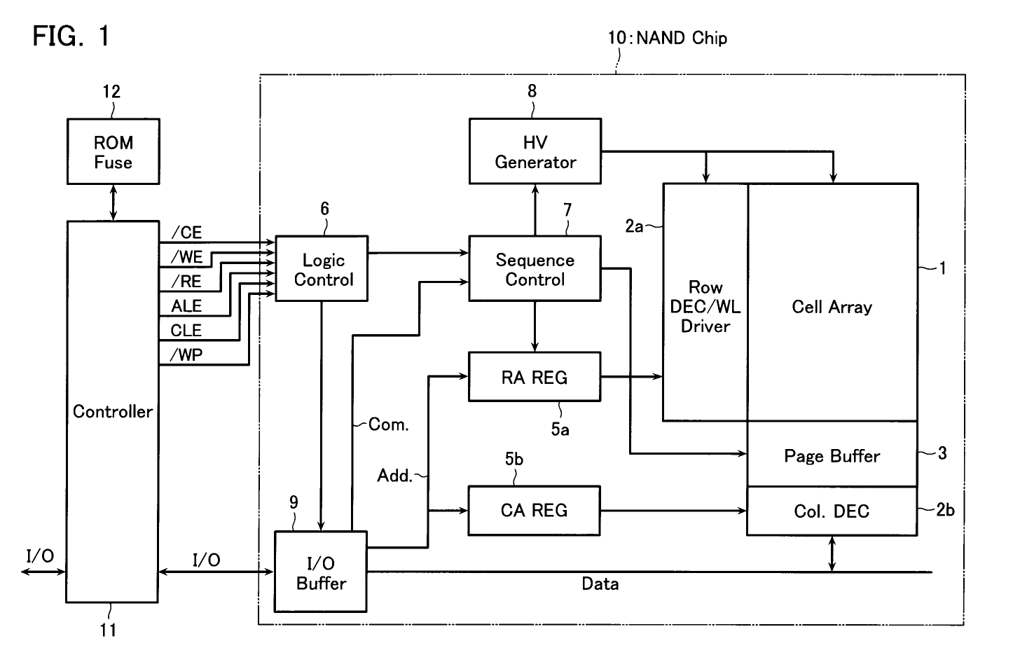

FIG. 1 is a block diagram showing the configuration of a NAND type flash memory according to the first embodiment of the present invention. The NAND type flash memory includes a NAND chip 10, a controller 11 that controls the NAND chip 10, and a ROM fuse 12 that stores write state information of the NAND chip 10. While the ROM fuse 12 has been shown outside the NAND chip 10 in FIG. 1, but a ROM fuse block (not shown) inside the NAND chip 10 may be caused to store the information so that data is transferred from the NAND chip 10 to the controller 11 during power-on of the system.

As described later, a memory cell array 1 that constitutes the NAND chip 10 comprises a plurality of floating gate type memory cells MC arranged like a matrix. A row decoder/word line driver 2a, a column decoder 2b, a page buffer 3, and a high-voltage generator 8 constitute a data writing/reading circuit that writes/reads data to/from the memory cell array 1 in units of pages. The row decoder/word line driver 2a drives word lines and selector gate lines of the memory cell array 1. The page buffer 3 has a sense amplifier circuit and a data holding circuit for one page to read data from the memory cell array 1 or to write data to the memory cell array 1 in units of pages.

Read data for one page of the page buffer 3 is sequentially column-selected by the column decoder 2b and output to an external I/O terminal via an I/O buffer 9. Write data supplied from the I/O terminal is selected by the column decoder 2b before being loaded into the page buffer 3. Write data for one page is loaded into the page buffer 3. Row and column address signals are input via the I/O buffer 9 and transferred to the row decoder 2a and the column decoder 2b respectively. A row address register 5a holds an erasing block address in an erasing operation and a page address in a write or read operation. A start column address for write data loading before starting a write operation or a start column address for a read operation is input into a column address register 5b. The column address register 5b holds an input column address until write enable/WE or read enable/RE is toggled under predetermined conditions.

A logic control circuit 6 controls input of a command or address or input/output of data based on a control signal such as a chip enable signal/CE, command enable signal CLE, address latch enable signal ALE, write enable signal/WE, and read enable signal/RE. A read operation or write operation is performed by command. After receiving a command, a sequence control circuit 7 exercises sequence control of a read, write, or erase operation. The high-voltage generator 8 is controlled by the sequence control circuit 7 to generate predetermined voltages necessary for various operations.

The controller 11 exercises write and read control of data under conditions appropriate for the current write state of the NAND chip 10. It is needless to say that a portion of read control described later may be performed by the NAND chip 10.

The ROM fuse 12 is a write state information storage means for storing various kinds of write state information B, C, and L (details thereof will be described later) of the NAND chip 10 necessary for control by the controller 11 in a nonvolatile state.

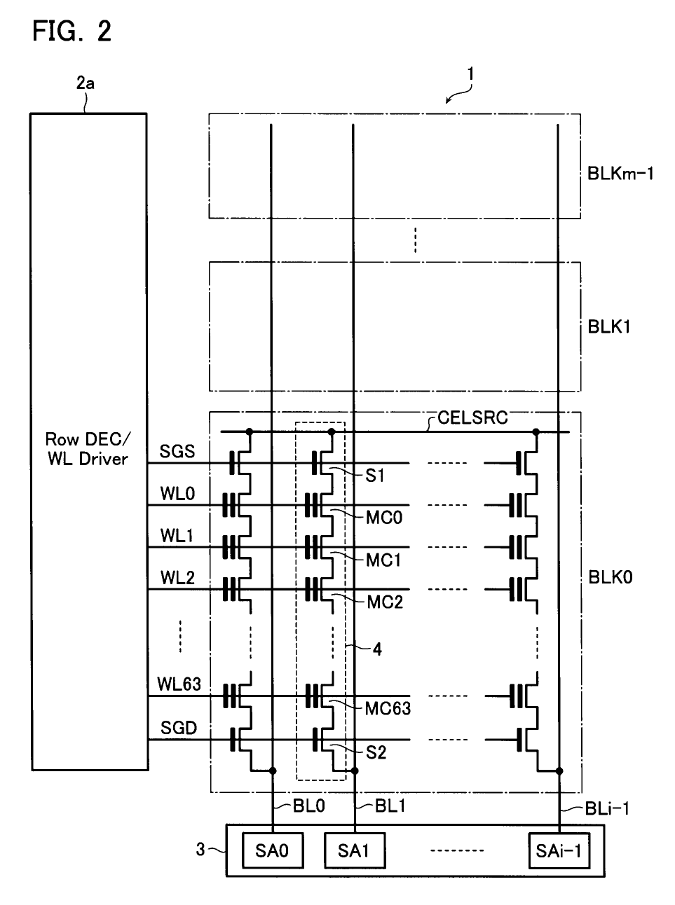

FIG. 2 shows a concrete configuration of the cell array 1. In this example, a NAND cell unit 4 comprises 64 memory cells MC0 to MC63 in series and selector gate transistors S1 and S2 connected to both ends thereof. The source of the selector gate transistor S1 is connected to a common source line CELSRC and the drain of the selector gate transistor S2 is connected to bit lines BL (BL0 to BLi-1). Control gates of the memory cells MC0 to MC63 are each connected to word lines (WL0 to WL63) and gates of the selector gate transistors S1 and S2 are connected to selector gate lines SGS and SGD respectively.

The range of a plurality of memory cells MC along one word line WL becomes a page, which is the unit of collective data read or data write. The range of a plurality of NAND cell units arranged in the word line WL direction constitutes a cell block BLK, which becomes the unit of collective data erasure. In FIG. 2, the cell array 1 comprises arranging a plurality of cell blocks BLK0 to BLKm-1 sharing the bit lines BL and the source line CELSRC in the bit line BL direction.

The word lines WL and the selector gate lines SGS and SGD are driven by the row decoder 2a. Each bit line BL is connected to sense amplifier circuits SA (SA0 to SAi-1) of the page buffer 3.

Next, operations of the present embodiment constituted as described above will be described.

Note that a “page” in a description that follows has three different meanings.

The first meaning is a “page” as a collective data access unit along one word line and in this case, all memory cells connected to a word line are accessed in one operation of access (ABL) or every other memory cell is accessed (BL shielding). In the former case, the page may be called an “even page” or an “odd page” depending on whether the number of the word line is even or odd. In the latter case, a plurality of memory cells connected to the same word line is divided into an “even page” and an “odd page”.

The second meaning is a “page” showing the level of hierarchy of stored data when multi-bit data is stored in one memory cell and in this case, the page is called the L (Lower) page, M (Middle) page, U (Upper) page and the like.

The third meaning is a “page” to determine the access order in consideration of the data access unit and the level of hierarchy of stored data and, for example, 128 pages are allocated for ABL two-bit data for 64 word lines and 192 pages are allocated for ABL three-bit data. A last page address L and an access page address P described later are addresses in units of the third page meaning.

In the first embodiment, a case in which an ABL (All Bit Line) type sense amplifier is used as the sense amplifier circuit SA is shown. As shown in FIG. 3, the ABL type makes simultaneous reading of adjacent bit lines possible by continuing to flow a current to the bit line BLi during sense operation and fixing the bit line potential to a fixed potential to eliminate the amplitude of the bit line BLi and to prevent an occurrence of capacitive coupling noise between adjacent bit lines.

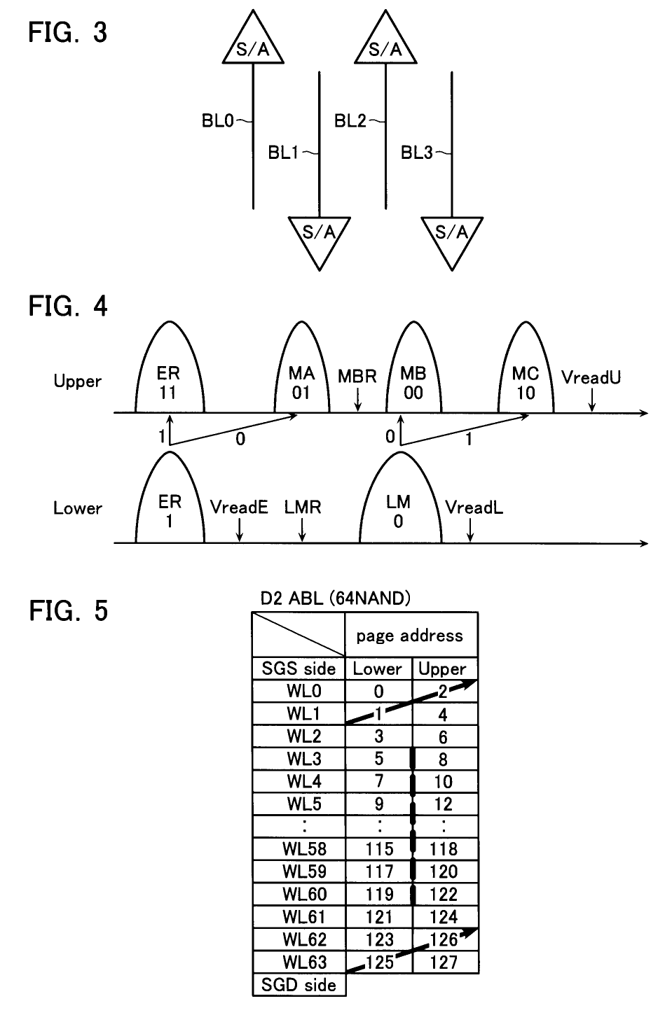

Also in the first embodiment, 2-bit (two-bit) data (D2) is stored in one memory cell MC. FIG. 4 shows threshold distributions of each memory cell MC when 2-bit data is written in two operations of the L page writing and U page writing. The threshold of all memory cells MC in a block is set to the lowest “ER (erase)” level by block erasure operation. Then, in the L page writing, the L page is written in such a way that the threshold is raised to the “LM” level for the memory cells of L page data “0”. The threshold “LM” level changes under the influence of adjacent memory cells on which a write operation is performed later and the threshold distribution width spreads. However, in the next U page writing, four narrow threshold distributions “ER”, “MA”, “MB”, and “MC” corresponding to data “11”, “01”, “00”, and “10” respectively are generated by further moving the threshold distribution in accordance with U page data. In this case, the lowest erasing level “ER” does not move, the next lowest “MA” level shifts from the erasing level “ER”, and higher threshold distributions “MB” and “MC” shift from the higher threshold distribution “LM”.

FIG. 5 shows the page access order in such a write operation. When an L page and a U page are each written to different page addresses, pages addresses 0 to 127 necessary to write 2-bit data to each memory cell connected to the word lines WL0 to WL63 are allocated, for example, as illustrated in FIG. 5. That is, an operation in which an L page is written to the memory cell of some word line WLk, a U page is written by returning to the memory cell of previous word line WLk−1, and then an L page is written by advancing two word lines is repeated. Accordingly, an influence of threshold fluctuations on a cell to which a U page is written by a write operation to adjacent memory cells to be performed later can be minimized.

As write state information by this writing, parameters B, C, and L shown below are stored in the ROM fuse 12:

B: Write state of the cell to which data is written lastly (2 bits)
11: Attempted to write, but failed
10: Written, but interrupted due to power failure or the like
01: Written, but insufficient
00: Successfully written

C: Block erasure/write state (1 bit)
1: Block immediately after erasure and blank
0: Block to which some kinds of data is written

L: Last page address (address of the page on which write processing is performed lastly)

The write state information is stored for each memory block BLK constituting the memory cell array 1. Writing timing is arbitrary and data may be written, for example, when the concerned block is erases or becomes an acquired defective block, or data is newly written to the block. Or, information L may be written in the controller 11 so that the information L is written from the controller 11 to the ROM fuse 12 as a background job in a period when users do not access.

Next, read operations will be described.

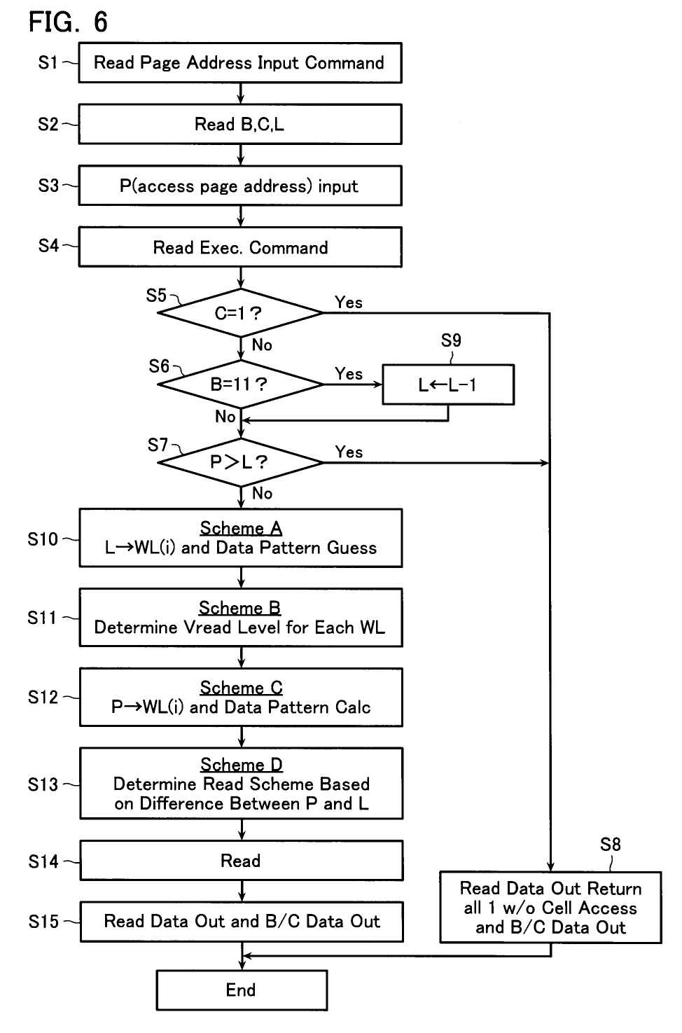

FIG. 6 is a flow chart showing read operations in the controller 11.

First, when an input command of an access page address is provided (S1), write state information B, C, and L is read (S2) and subsequently, an access page address P is input (S3). Then, a read execution command is executed (S4).

In the read operation, first whether the parameter C is equal to “1” is determined (S5). If C=1, the block including the page attempted to read is immediately after erasure and blank and thus, all data “1” is output as read data (S8) without accessing a cell before read processing is terminated.

If C=0 at step S5, whether B is “11” is determined (S6) and if B=11, 1 is subtracted from the last page address L (S9). This is because no data is written in the write operation after the last page address L being updated and thus, the last page address L is brought back to the previous state. If B is determined to be other than 11 at step S6, the last page address L is left unchanged to continue to step S7.

At step S7, the access page address P and the last page address L are compared. If the access page address P is larger than the last page address L, the memory cell from which data is about to be read is considered to be blank and also in this case, all data “1” is output as read data (S8) without accessing a cell before read processing is terminated.

If, on the other hand, the access page address P is equal to or less than the last page address L at step S7, a page to which data is already written will be accessed and thus, the cell needs to be accessed in accordance with the write state.

Here, the cell is accessed in accordance with the write state after going through 4-stage processing of Scheme A to Scheme D (S10 to S13). Scheme A (S10) is processing to estimate the data write state of the memory cell MC connected to each word line WL from the last page address L. Scheme B (S11) is processing to decide the level of the read voltage Vread applied to each word line WL in accordance with the estimated write state. Scheme C (S12) is processing to determine the word line WL(i) to be accessed from the access page address P and whether an L page or U page is accessed. Scheme D (S13) is processing to determine whether to read data from adjacent cells in advance in accordance with a difference between the access page address P and the last page address L and to decide the read voltage Vread.

Concrete processing of these Schemes A through D will be described below.

[Scheme A]

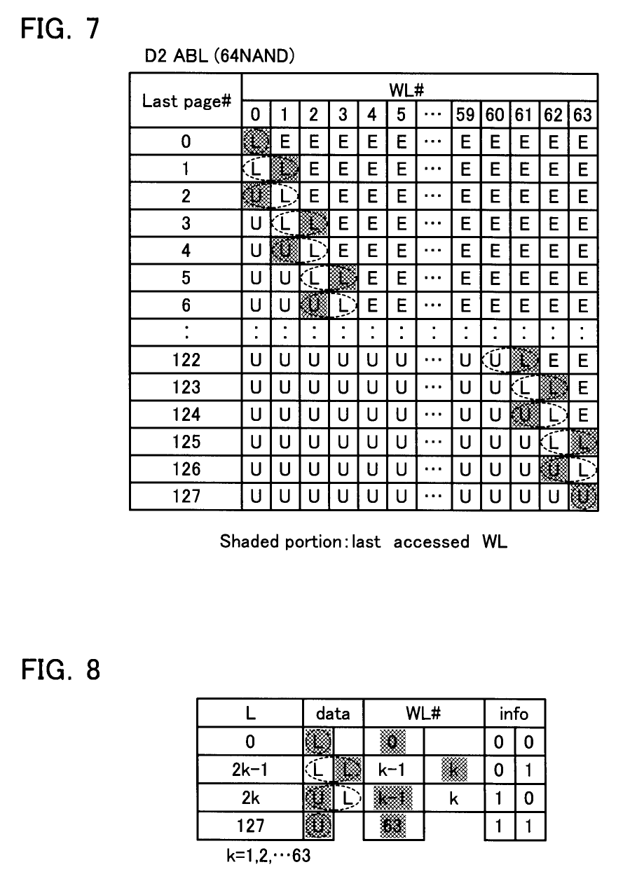

In Scheme A, first the write state of the page immediately below each word line WLi is estimated from the last page address L (S10). The write state depends on the write order shown in FIG. 5. FIG. 7 is a diagram showing an estimation pattern of the write state based on the write order in FIG. 5. Shaded portions indicate the word lines WLi accessed lastly. For example, if the last page address L is “1”, data is written to the L page of the word lines WL0 and WL1, the word lines WL2 to WL63 are in an erase state, and the last write page is the L page connected to the word line WL1. Similarly, for example, if the last page address L is “6”, data is written to the U page of the word lines WL0 to WL2 and the L page of the word line WL3, the word lines WL4 to WL63 are in an erase state, and the last write page is the U page connected to the word line WL2. If the above pattern is focused on, excluding the last page address L=0 and 127, a pattern in which “U” on the left side and/or “E” on the right side is attached to a pattern of “LL” in an odd page or “UL” in an even page is recognized and generalization thereof produces four patterns shown in FIG. 8 so that the write state of each word line WL can be estimated from 2-bit information “info”.

[Scheme B]

Next, in Scheme B, the read voltage Vread provided to each word line WLi is decided (S11). That is, as is evident from the threshold pattern in FIG. 4, the read voltage Vread to provide an ON state during reading for the write state of each memory cell is VreadE in the “ER” state, VreadL in the L page write state, and VreadU in the U page write state with the relation VreadE≦VreadL≦VreadU. Thus, compared with a case in which VreadU is applied to word lines of all non-selected pages, stress on memory cells is significantly reduced. As concrete processing, it is desirable from the viewpoint of circuit scale and processing speed that word line positions and each data level of E, L, and U be calculated from the last page address L by the controller 11, “info” bits shown in FIG. 8 be output from the controller 11 to the NAND chip 10, and the read voltage VreadE, VreadL, or VreadU be provided to each word line WLi by the NAND chip 10 in accordance with the “info” bits.

[Scheme C]

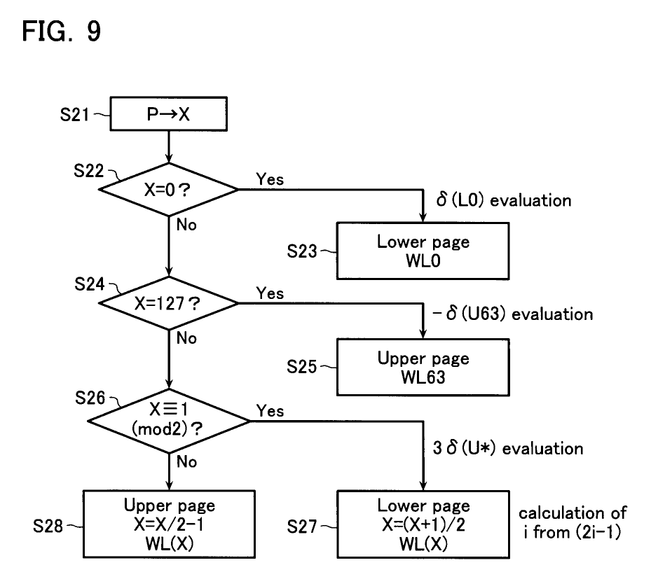

Next, in Scheme C, the word line WLi corresponding to the access page address P and which page of L/U is accessed are determined (S12). This processing is processing to determine the word line number and one of L/U page from the page addresses shown in FIG. 5. FIG. 9 is a flow chart showing this processing. First, the access page address P is substituted into a variable X (S21). If X is “0” (S22), the L page of the word line WL0 is set to be a page to be read (S23). If X is “127” (S24), the U page of the word line WL63 is set to be a page to be read (S25). If X is other than “0” and “127” and if the remainder after dividing X by 2 is “1” (that is, X is odd) (S26), the L page of the word line WL(X) of the number calculated by X=(X+1)/2 is set to be a page to be read (S27). If the remainder after dividing X by 2 is “0” (that is, X is even) (S26), the U page of the word line WL(X) of the number calculated by X=X/2−1 is set to be a page to be read (S28).

[Scheme D]

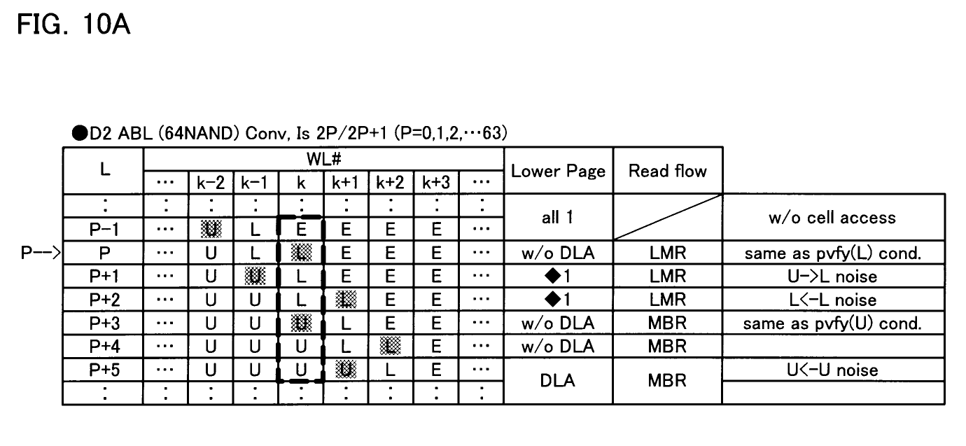

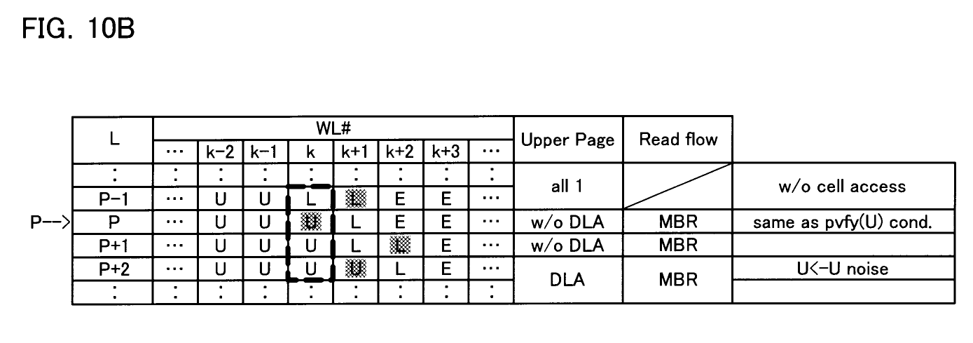

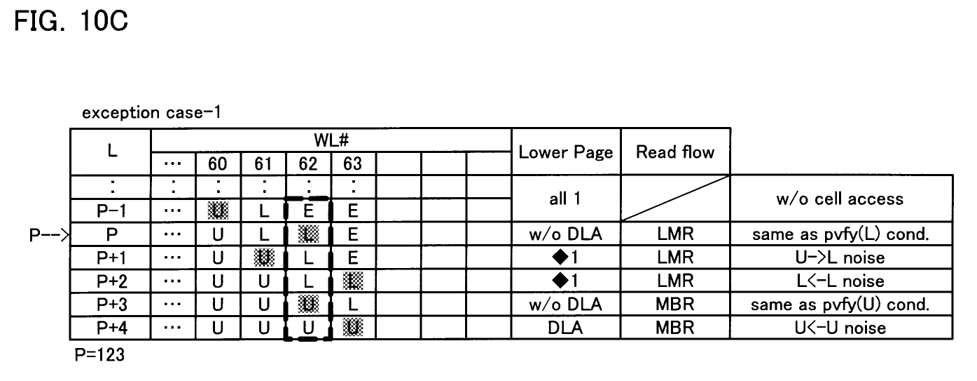

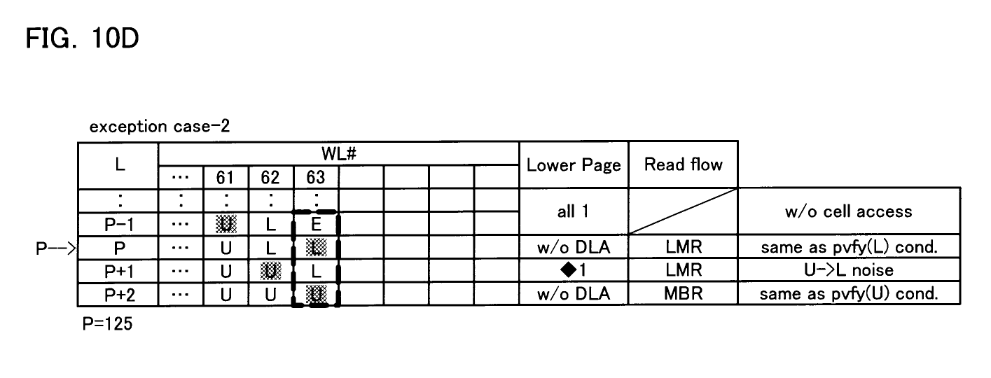

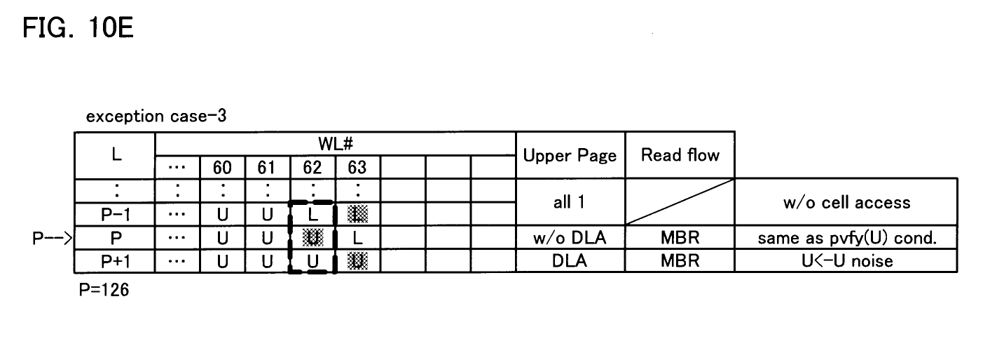

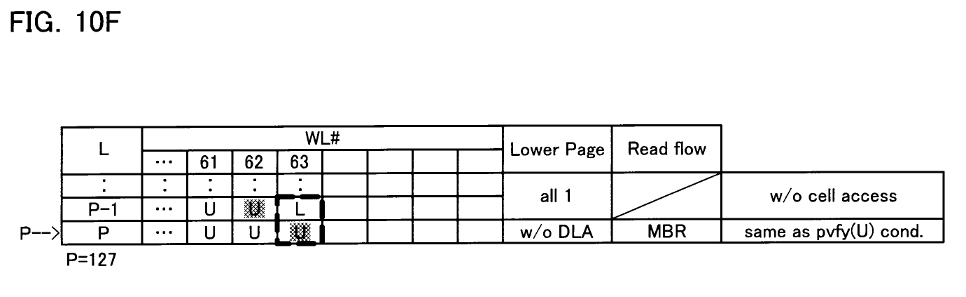

Next, in Scheme D, whether to read adjacent memory cells in advance in accordance with a difference between the access page address P and the last page address L and the read voltage Vread are determined (S13). FIG. 10A to FIG. 10F are diagrams illustrating Scheme D.

FIG. 10A shows a case in which the L page of the word line WLk is read. A portion in which P−1, P, P+1, . . . are written in the left column of FIG. 10A shows whether the last page address L is P−1, P, P+1, . . . and if L is P, this means that the access page matches the last page. Shaded portions in the table indicate pages to which data is written lastly. “w/o” of symbols in the table is an abbreviation of “without”. “DLA” is an abbreviation of “Direct Look Ahead read” and indicates advance read processing of adjacent cell data. “w/o DLA” means that DLA is unnecessary and “DLA” means execution of DLA. “♦1” means that while being affected by adjacent cells, no serious problem will be caused even if DLA is not executed.

If, for example, the last page address L and the access page address P match, the word line WLk from which data is about to be read is the L page to which data is written lastly and since not susceptible to adjacent cells in this case, data is read by providing LMR in FIG. 4 to the word line WLk without executing DLA. If, on the other hand, the last page address L is P+1 or P+2, the threshold of the L page of the word line WLk is affected by writing of the U page of the word line WLk−1. In this case, however, data is read from the L page and thus, the problem is insignificant. Attachment of ♦1 has such a meaning. If the last page address L is P+5 or greater, in contrast, the threshold of the U page of the word line WLk is affected by writing of the U page of the word line WLk+1. In this case, processing by DLA becomes necessary during reading. The reading level provided to the word line WLk to read the L page is set at LMR in FIG. 4 when writing of the L page is completed and at MBR in FIG. 4 when writing of the U page is completed.

FIG. 10B shows a case in which the U page of the word line WLk is read. Also in this case, if the last page address L and the access page address P are equal, read processing of the page of the word line WLk from which data is about to be read is performed without executing DLA because of writing of the U page is performed immediately before. If, on the other hand, the last page address L is P+2, the U page of the word line WLk+1 to which data is written lastly affects the U page of the word line WLk from which data is about to be read. In this case, DLA is executed.

FIG. 10C to FIG. 10F are tables showing processing when data of end word lines is read and FIG. 10C shows L page reading of the word line WL62, FIG. 10D shows L page reading of the word line WL63, FIG. 10E shows U page reading of the word line WL62, and FIG. 10F shows U page reading of the word line WL63. Content thereof is similar to that described above and thus, a detailed description thereof is omitted.

According to the present embodiment, as described above, by storing write state information such as the last page address L of the memory cell array 1 in the ROM fuse 12, write conditions of the page read from the access page address P are grasped when data is read and data “1” is read without access if the write state is clearly an erase state, data is normally read if estimated that the cell is not affected by adjacent cells, and DLA is executed if estimated that the cell is affected by adjacent cells so that the average time of access can be reduced compared with a case in which DLA is executed for all cells. Moreover, the read voltage applied to word lines can be minimized and the number of times of applying the voltage can be minimized so that stress on memory cells can be reduced.

### Second Embodiment

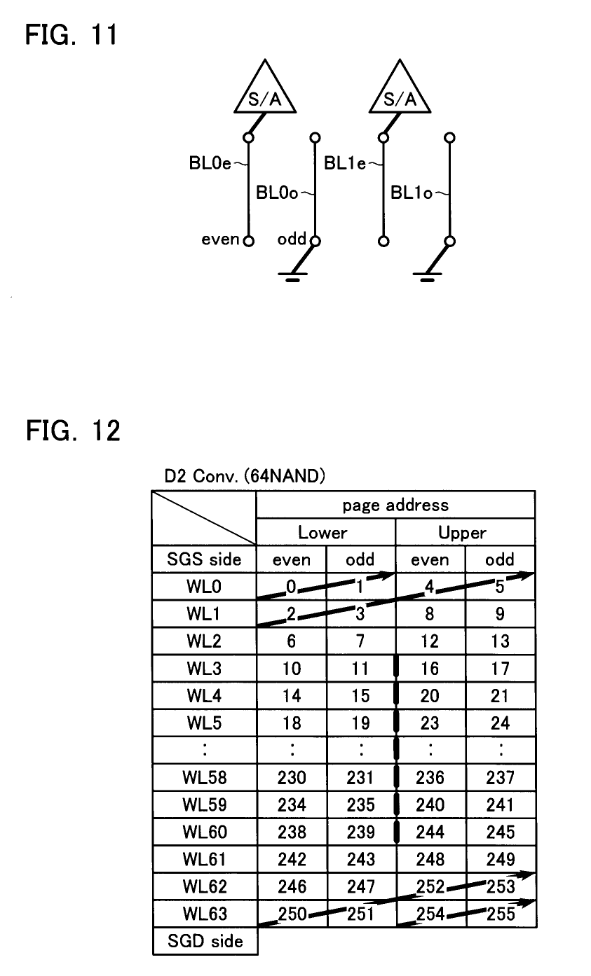

In the second embodiment, a case in which a BL shield type sense amplifier is used as the sense amplifier circuit SA is shown. As shown in FIG. 11, the BL shield type is a sense amplifier in which every other bit line BL is connected to the sense amplifier and bit lines not connected to the sense amplifier are fixed to the ground potential to prevent an occurrence of noise due to an influence from adjacent bit lines. In this case, writing and reading occur alternately in even pages and odd pages.

Otherwise, the configuration is the same as that of the first embodiment and thus, a detailed description thereof is omitted.

FIG. 12 shows the page access order in a data write operation. When an even page and an odd page of an L page and those of a U page are each written to different page addresses, pages addresses 0 to 255 necessary to write 2-bit data to each memory cell connected to the word lines WL0 to WL63 are allocated, for example, as illustrated in FIG. 12. That is, an operation in which if data of an even page of an L page is written to some page, data is written to an odd page of the L page and then, an even page and an odd page of a U page of the previous word line before advancing two lines to write data to an even page and an L page is repeated. Accordingly, an influence of threshold fluctuations on a cell to which a U page is written by a write operation to adjacent memory cells to be performed later can be minimized.

Next, read operations will be described.

Read operations in the present embodiment are different from those in the first embodiment in Schemes A, C, and D and thus, only these different portions will be described and a description of other processing is omitted.

[Scheme A]

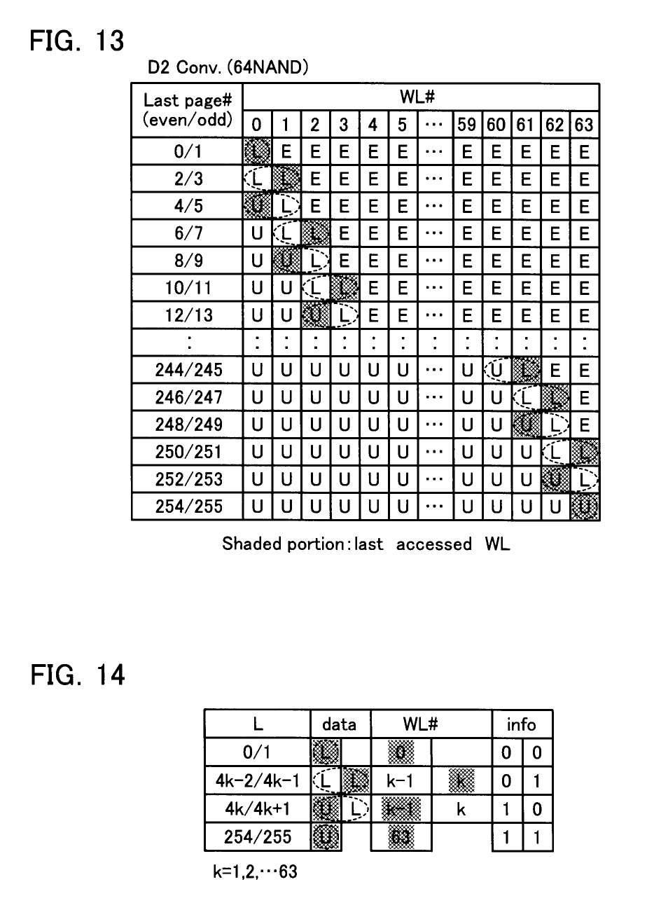

In Scheme A, the write state of each page is estimated from the last page address L. In the present embodiment, page addresses for even pages and odd pages are needed, which makes the number of page addresses double that of page addresses in the first embodiment. FIG. 13 is a diagram showing an estimation pattern of the write state based on the write order in FIG. 12. Here, shaded portions indicate the word lines WLi accessed lastly. For example, if the last page address L is the even page “2” or the odd page “3”, data is written to the L page of the word lines WL0 and WL1, the word lines WL2 to WL63 are in an erase state, and the last write page is the L page connected to the word line WL1. If the last page address L is the even page “12” or the odd page “13”, data is written to the U page of the word lines WL0 to WL2 and to the L page of the word line WL3, the word lines WL4 to WL63 are in an erase state, and the last write page is the U page connected to the word line WL2. If the above pattern is focused on, excluding the last page address L=0, 1, 254 and 255, a pattern in which “U” on the left side and/or “E” on the right side is attached to a pattern of “LL” in an odd page or “UL” in an even page is recognized and generalization thereof produces four patterns shown in FIG. 14 so that the write state of each word line WL can be estimated from 2-bit information “info”.

[Scheme C]

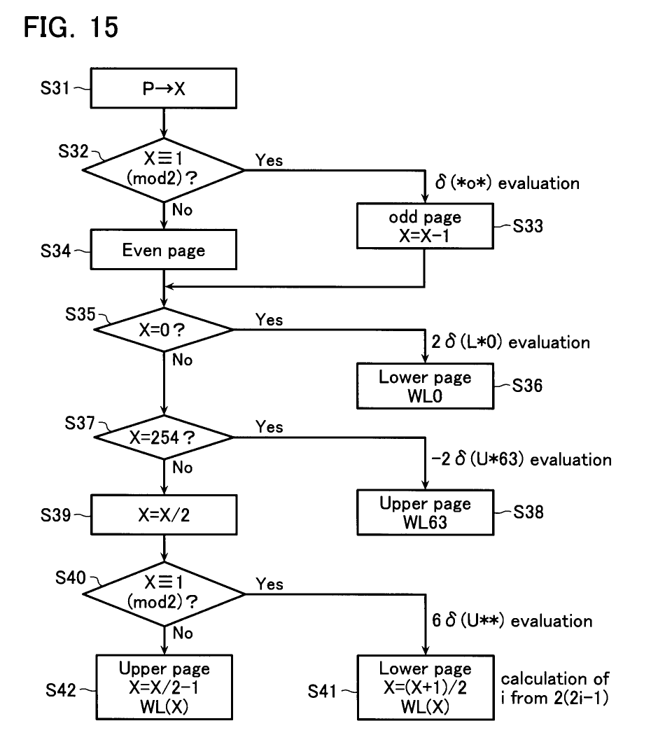

In Scheme C, the word line WLi corresponding to the access page address P and which page of L/U is accessed are determined. This processing is processing to determine the word line number and one of L/U page from the page addresses shown in FIG. 12. FIG. 15 is a flow chart showing this processing. First, the access page address P is substituted into the variable X (S31). Next, whether the remainder after dividing X by 2 is “1” is determined (S32) and if the remainder is “1”, the page is an odd page and 1 is subtracted from X (S33) and if the remainder is “0”, the page is an even page and left unchanged (S35). Next, if X is “0” (S35), the L page of the word line WL0 is set to be a page to be read (S36). If X is “254” (S37), the U page of the word line WL63 is set to be a page to be read (S38). If X is other than “0” and “254”, X is divided by 2 (S39) and if X is odd (S40), the L page of the word line WL(X) of the number calculated by X=(X+1)/2 is set to be a page to be read (S41). If X is even (S40), the U page of the word line WL(X) of the number calculated by X=X/2−1 is set to be a page to be read (S42).

[Scheme D]

Next, in Scheme D, whether to read adjacent memory cells in advance in accordance with a difference between the access page address P and the last page address L and the read voltage Vread are determined. This processing is the same as that in the first embodiment except that the processing follows a table obtained by replacing P in the left column of each table in FIG. 10A to FIG. 10F in the first embodiment by 2P (even page) or 2P+1 (odd page).

### Third Embodiment

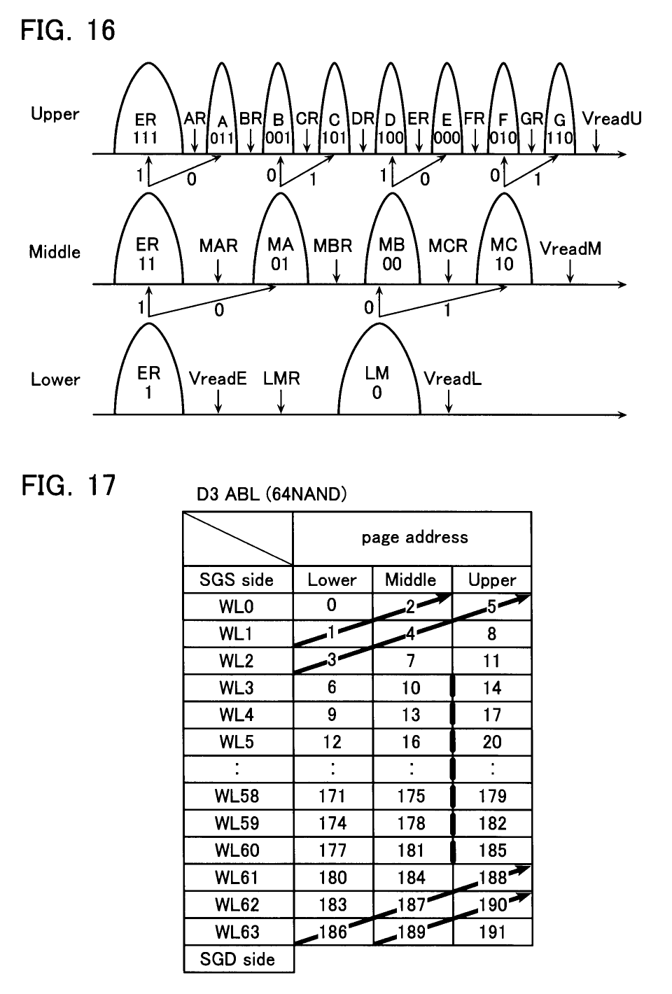

In the third embodiment, like the first embodiment, an ABL type sense amplifier is used as the sense amplifier circuit SA, but unlike the first embodiment, 3-bit data (D3) is stored in one memory cell MC. FIG. 16 shows threshold distributions of each memory cell MC when 3-bit data is written in three operations of the L (Lower) page writing, M (Middle) page writing, and the U (Upper) page writing. The threshold of all memory cells MC in a block is set to the lowest “ER (erase)” level by block erasure. Then, in the L page writing, the L page is written in such a way that the threshold is raised to the “LM” level for the memory cells of L page data “0”. In the M page writing, four threshold distributions “ER”, “MA”, “MB”, and “MC” corresponding to data “11”, “01”, “00”, and “10” respectively are generated from these two threshold distributions “ER” and “LM”. Further, in the U page writing, eight threshold distributions “ER”, “A”, “B”, “C”, “D”, “E”, “F”, and “G” corresponding to data “111”, “011”, “001”, “101”, “100”, “000”, “010”, and “110” respectively are generated from these four threshold distributions “ER”, “MA”, “MB”, and “MC”.

FIG. 17 shows the page access order in such a write operation. When an L page, an M page, and a U page are each written to different page addresses, pages addresses 0 to 191 necessary to write 3-bit data to each memory cell connected to the word lines WL0 to WL63 are allocated, for example, as illustrated in FIG. 17. That is, after writing data of an L page to some page, an M page is written by returning to the previous page and further, a U page is written by returning to the previous page. Next, the L page is written by advancing three pages to repeat the same operation.

Next, read operations will be described.

Read operations in the present embodiment are different from those of the above embodiments only in Schemes A, C, and D and thus, only these different portions will be described and a description of other processing is omitted.

[Scheme A]

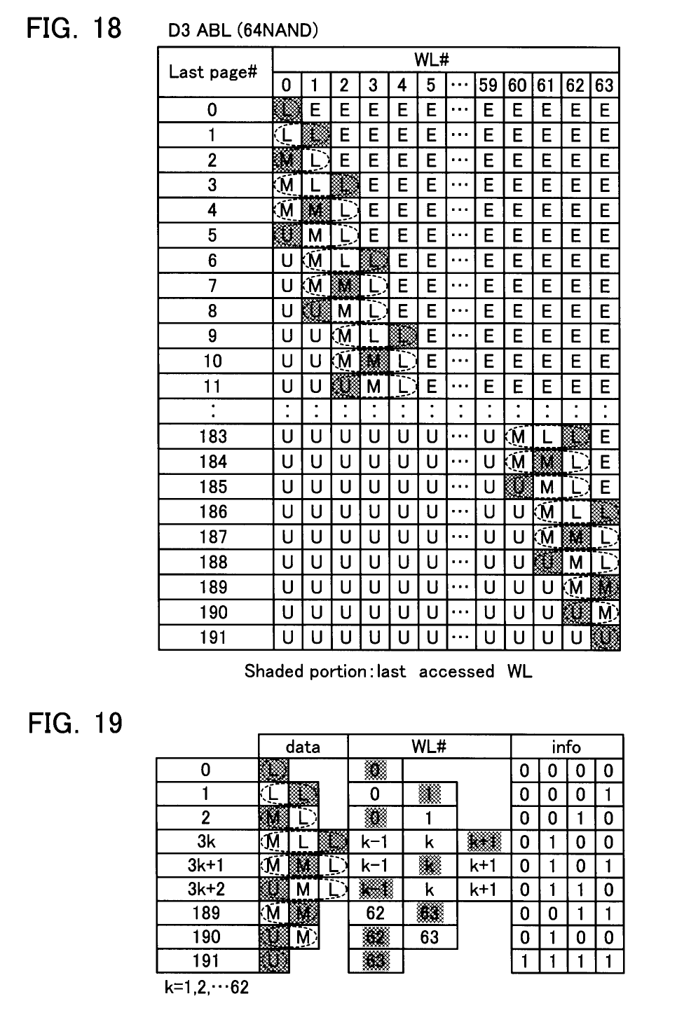

In Scheme A, the write state of each page is estimated from the last page address L. In the present embodiment, page addresses are allocated to L pages, M pages, and U pages, which make the number of page addresses 1.5 times that of page addresses in the first embodiment. FIG. 18 is a diagram showing an estimation pattern of the write state based on the write order in FIG. 17. Here, shaded portions indicate the word lines WLi accessed lastly. For example, if the last page address L is “3”, data is written to the M page of the word line WL0 and the L page of the word lines WL1 and WL2, the word lines WL3 to WL63 are in an erase state, and the last write page is the L page connected to the word line WL2. If the last page address L is “11”, data is written to the U page of the word lines WL0 to WL2, to the M page of the word line WL3, and to the L page of the word line WL4, the word lines WL5 to WL63 are in an erase state, and the last write page is the U page connected to the word line WL2. If the above pattern is focused on, excluding the last page address L=0, 1, 2, 189, 190, and 191, a pattern in which “U” on the left side and/or “E” on the right side is attached to a pattern of “MLL” in a 3k (k is an integer of 1 to 62) page, “MML” in a 3k+1 page, or “UML” in a 3k+2 page is recognized and generalization thereof produces nine patterns shown in FIG. 19 so that the write state of each word line WL can be estimated from 4-bit information “info”.

[Scheme C]

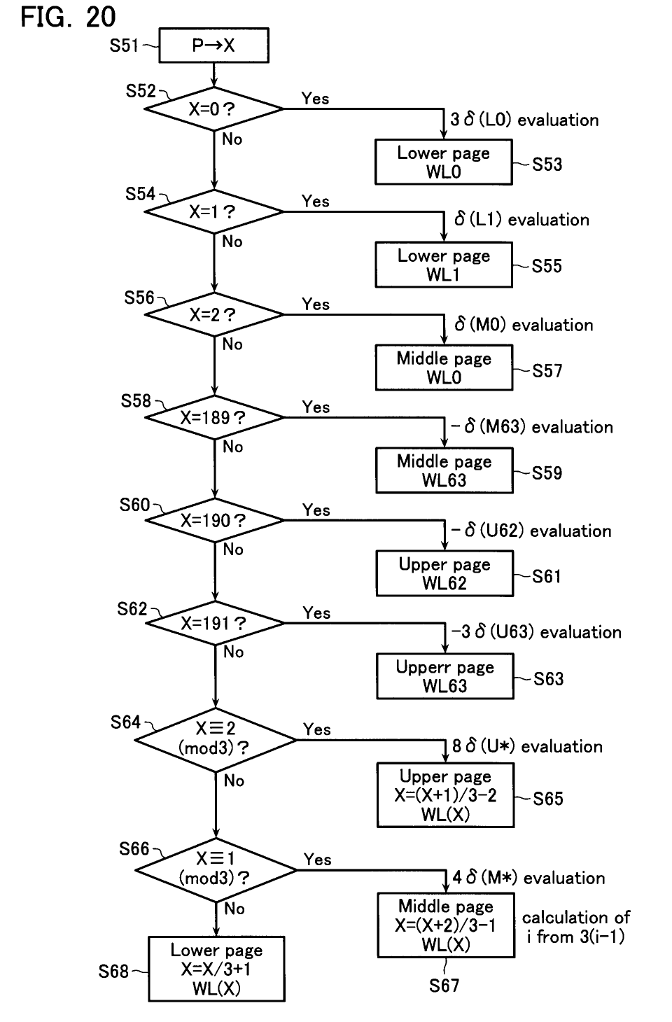

In Scheme C, the word line WLi corresponding to the access page address P and which page of L/U is accessed are determined. This processing is processing to determine the word line number and one of L/M/U page from the page addresses shown in FIG. 17. FIG. 20 is a flow chart showing this processing. First, the access page address P is substituted into the variable X (S51). Next, if X is “0”, the L page of the word line WL0 is set to be a page to be read, if X is “1”, the L page of the word line WL1, if X is “2”, the M page of the word line WL0, if X is “189”, the M page of the word line WL63, if X is “190”, the U page of the word line WL62, and if X is “191”, the U page of the word line WL63 (S52 to S63). If X is other than these values and if the remainder after dividing X by 3 is 2 (S64), the U page of the word line WL(X) of the number calculated by X=(X+1)/3−2 is set to be a page to be read (S65). If the remainder is 1 (S66), the M page of the word line WL(X) of the number calculated by X=(X+2)/3−1 is set to be a page to be read (S67). If the remainder is 0 (S66), the L page of the word line WL(X) of the number calculated by X=X/3+1 is set to be a page to be read (S68).

[Scheme D]

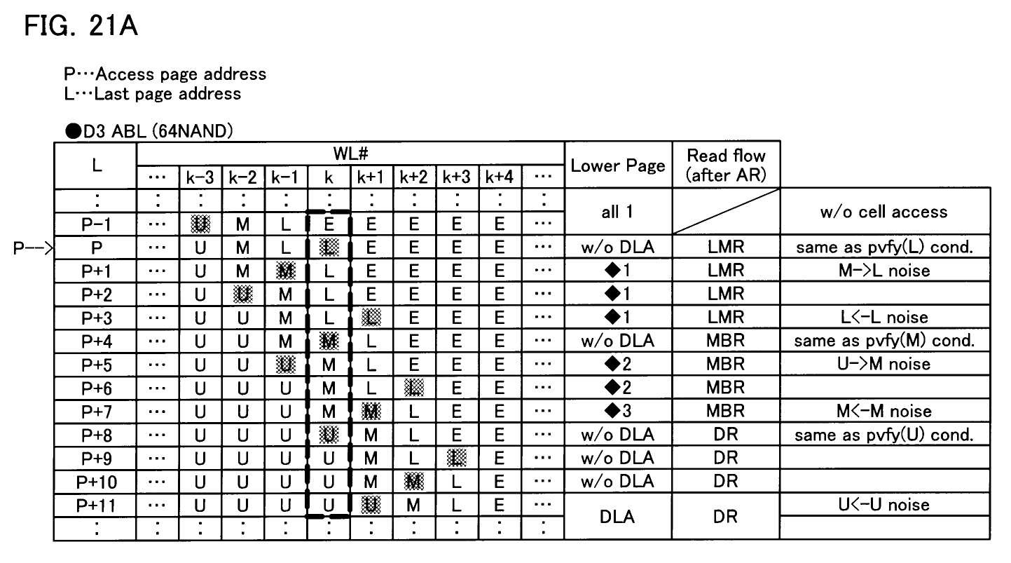

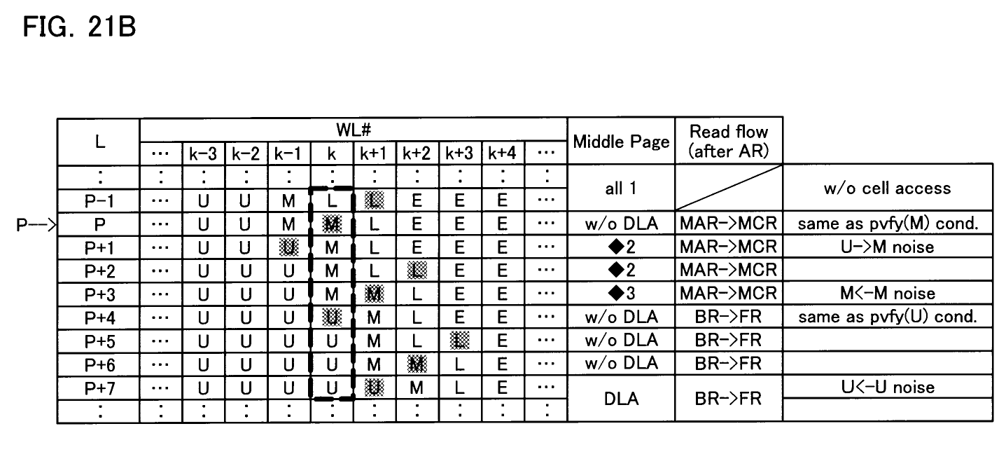

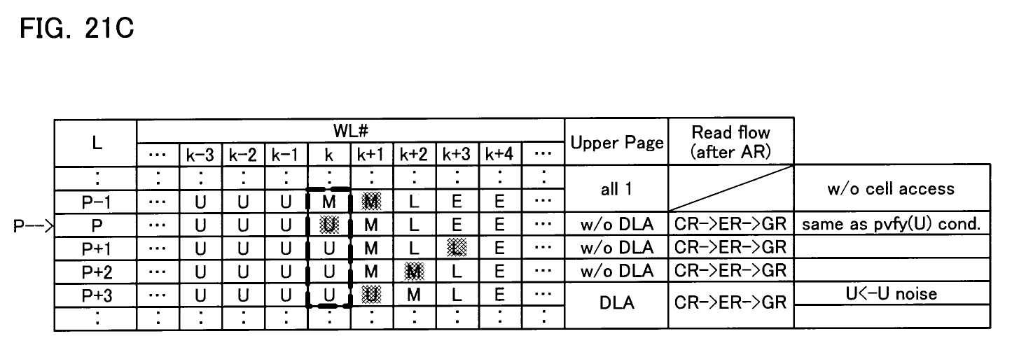

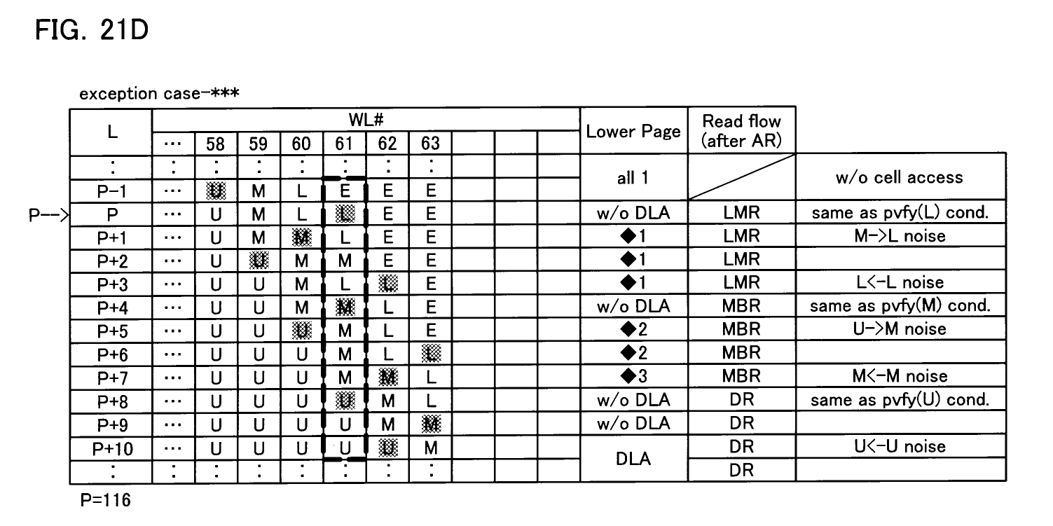

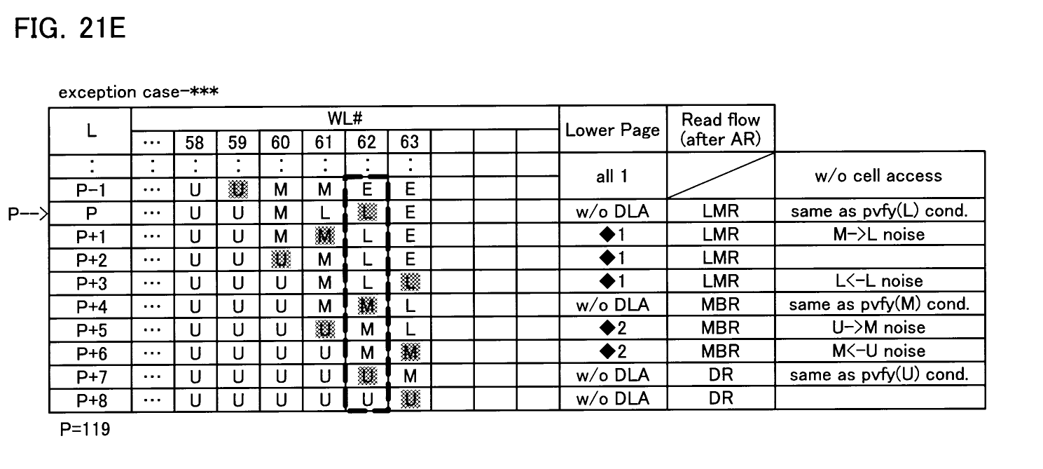

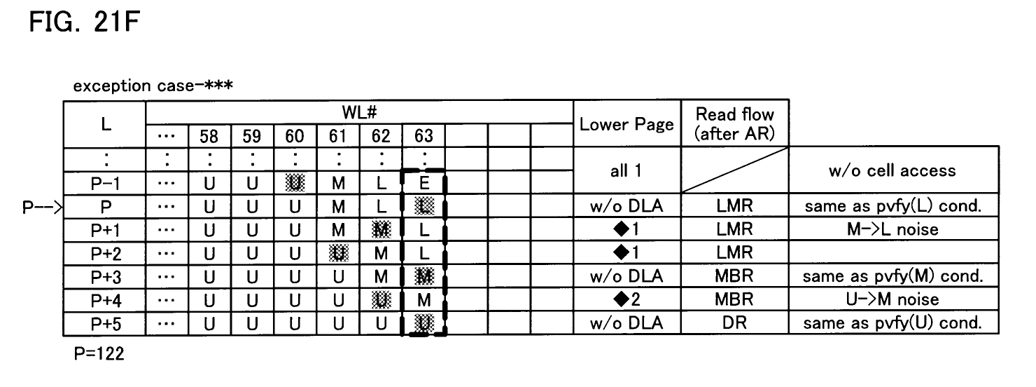

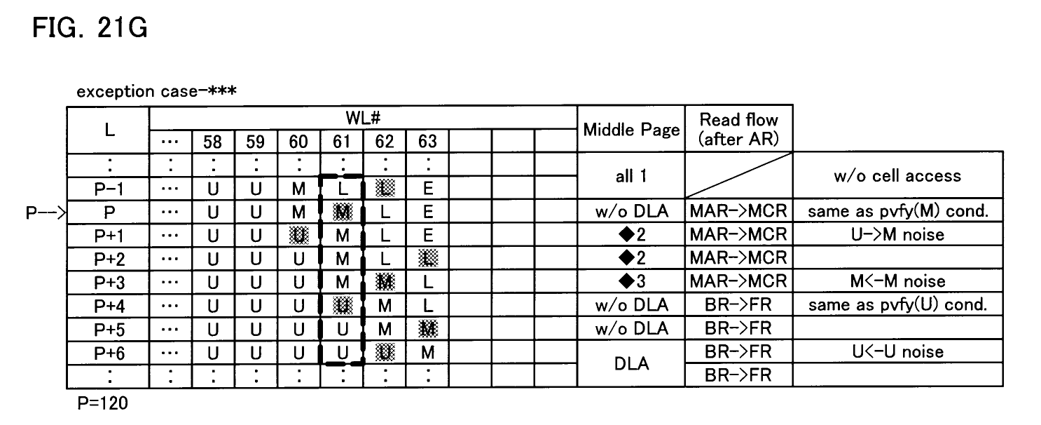

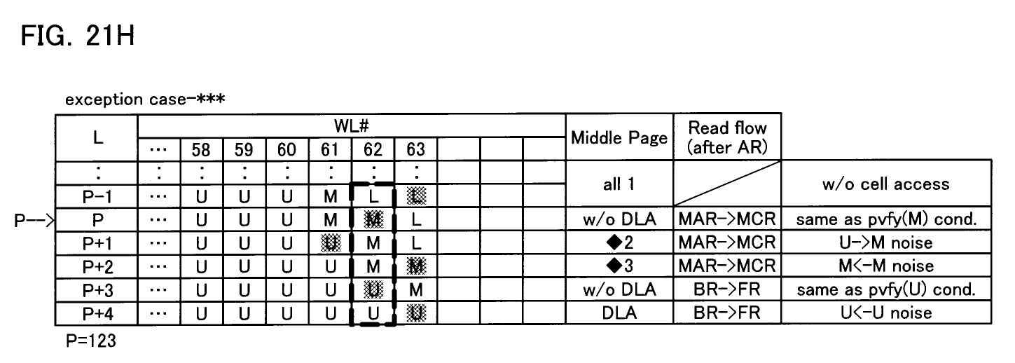

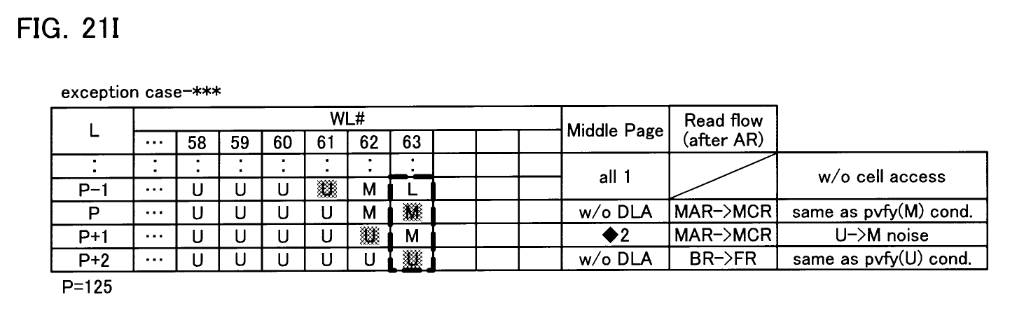

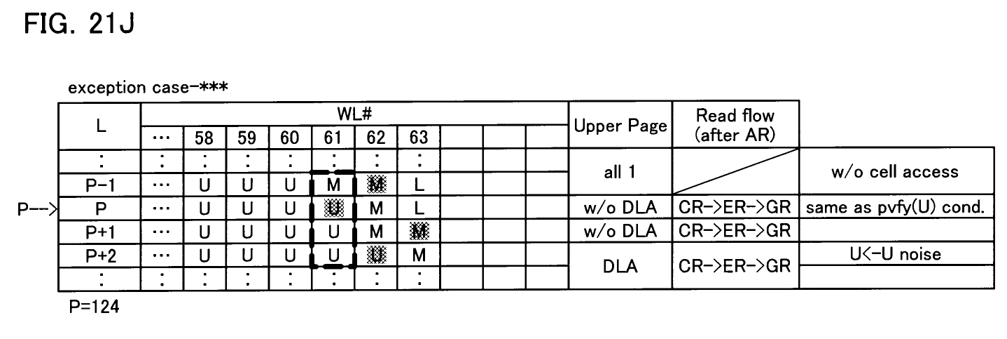

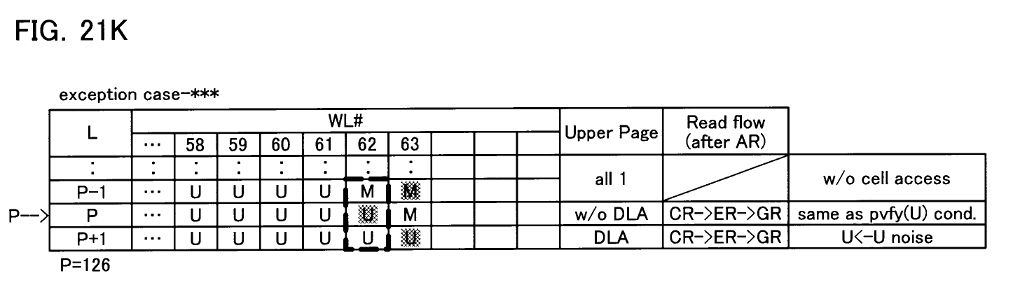

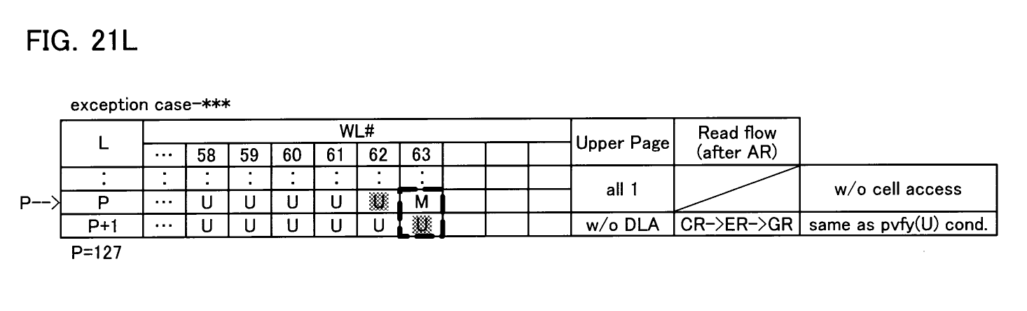

Next, in Scheme D, whether to read adjacent memory cells in advance in accordance with a difference between the access page address P and the last page address L and the read voltage Vread are determined. FIG. 21A to FIG. 21L are diagrams illustrating Scheme D.

FIG. 21A shows a case in which the L page of the word line WLk is read. ♦1 to 3 in FIG. 21A has the following meanings:

♦1→No serious problem will be caused even if DLA is not executed.

♦2→It is desirable to execute DLA.

♦3→DLA needs to be executed.

That is, the strength of necessity of DLA execution is:

♦1<♦2<♦3<DLA

If, for example, the last page address L and the access page address P match, the word line WLk from which data is about to be read is the L page to which data is written lastly and since not susceptible to adjacent cells in this case, data is read by providing LMR in FIG. 16 to the word line WLk without executing DLA. If, on the other hand, the last page address L is one of P+1 to P+3, the threshold of the L page of the word line WLk is affected by writing of the M page of the word line WLk−1. If the last page address L is one of P+5 to P+7, the threshold of the M page of the word line WLk is affected by writing of the U page of the word line WLk−1. Particularly if the last page address L is P+7, the threshold of the M page of the word line WLk is also affected by writing of the M page of the word line WLk+1. Therefore, ♦1 is attached to P+1 to P+3, ♦2 to P+5 and P+6, and ♦3 to P+7. Further, if the last page address L is P+11 or greater, the threshold of the U page of the word line WLk is affected by writing of the U page of the word line WLk+1. Therefore, in this case, it is necessary to execute DLA during reading. If, after verification based on the AR level in FIG. 16, writing up to the L page has terminated, the reading level provided to the word line WLk is set at LMR, if writing up to the M page has terminated, the word line WLk is set at MBR, and if writing up to the U page has terminated, the word line WLk is set at DR to read data in the L page.

FIG. 21B shows a case in which the M page of the word line WLk is read. Also in this case, if the last page address L and the access page address P are equal, read processing of the page of the word line WLk from which data is about to be read is performed without executing DLA because of writing of the M page immediately before. The read processing is performed by sequentially changing the threshold level from MAR to MCR in FIG. 16. If, on the other hand, the last page address L is one of P+1 to P+3, the U page of the word line WLk−1 affects the M page of the word line WLk from which data is about to be read. In this case, DLA is executed in accordance with a magnitude of influence thereof. If the last page address L is P+7 or greater, the threshold of the U page of the word line WLk is affected by writing of the U page of the word line WLk+1. Therefore, in this case, DLA is executed without fail during reading. If an M page is read from a memory cell to which a U page has been written, the word line level is set to BR, DR, and FR levels in FIG. 16 after AR verification.

FIG. 21C shows a case in which the U page of the word line WLk is read. Also in this case, if the last page address L and the access page address P are equal, read processing of the page of the word line WLk from which data is about to be read is performed without executing DLA because of writing of the U page immediately before. If the last page address L is P+1 or P+2, DLA is not executed because the U page of the word line WLk is not affected. If, on the other hand, the last page address L is P+3 or greater, the U page of the word line WLk+1 affects the U page of the word line WLk from which data is about to be read. In this case, DLA is executed. The U page is read by making level comparisons with CR, ER, and GR after AR verification.

FIG. 21D to FIG. 21L are tables showing processing when data of end word lines is read and FIG. 21D shows L page reading of the word line WL61, FIG. 21E shows L page reading of the word line WL62, FIG. 21F shows L page reading of the word line WL63, FIG. 21G shows M page reading of the word line WL61, FIG. 21H shows M page reading of the word line WL62, FIG. 21I shows M page reading of the word line WL63, FIG. 21J shows U page reading of the word line WL61, FIG. 21K shows U page reading of the word line WL62, and FIG. 21L U page reading of the word line WL63. Content thereof is similar to that described above and thus, a detailed description thereof is omitted.

### Fourth Embodiment

In the fourth embodiment, like the third embodiment, an ABL type sense amplifier is used as the sense amplifier circuit SA and 3-bit data (D3) is stored in one memory cell MC, but the data write order is different from that in the third embodiment.

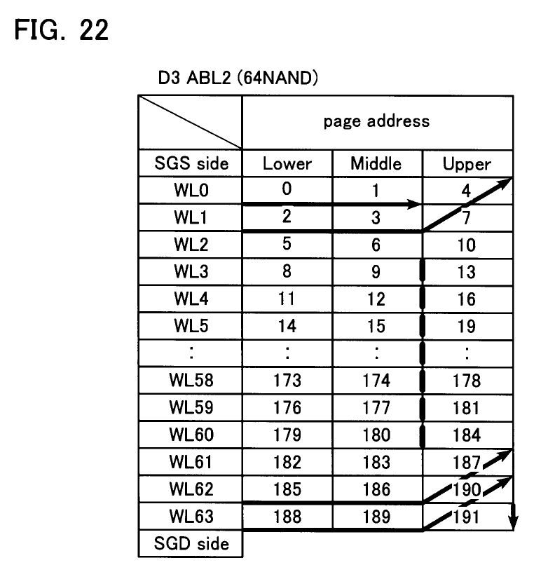

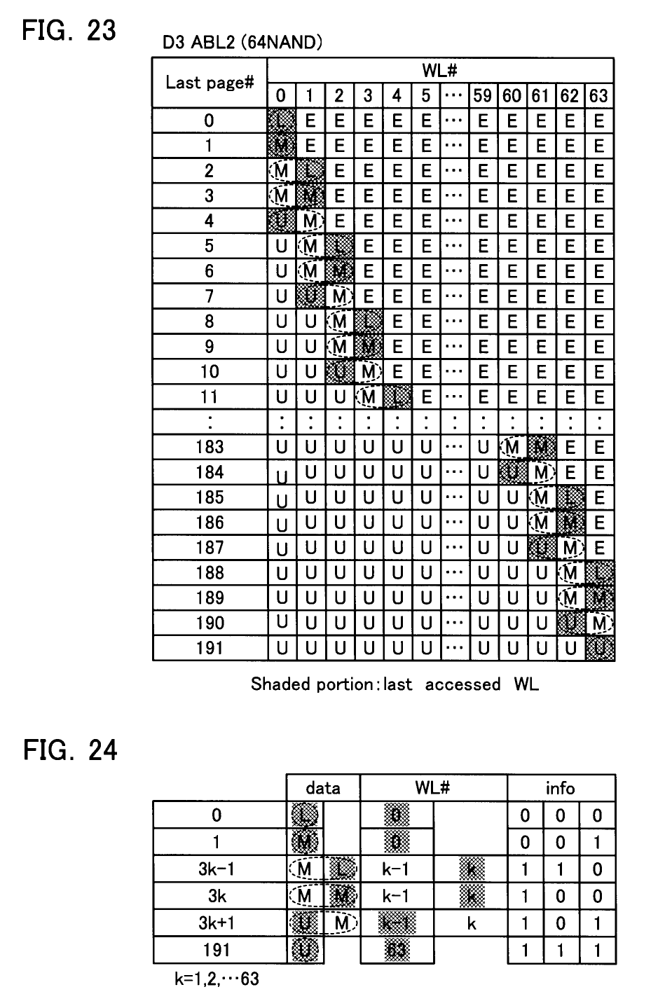

FIG. 22 shows the page access order in a write operation according to the present embodiment. After data of an L page is written to some page, an M page is written to the same page and then, a U page is written by returning to the previous page. Next, the L page is written by advancing two pages to repeat the same operation.

Next, read operations will be described.

Read operations in the present embodiment are different from those of the above embodiments only in Schemes A, C, and D and thus, only these different portions will be described and a description of other processing is omitted.

[Scheme A]

In Scheme A, the write state of each page is estimated from the last page address L. Excluding the last page address L=0, 1, and 191, the pattern in the present embodiment is a pattern in which “U” on the left side and/or “E” on the right side is attached to a pattern of “ML” in a 3k−1 (k is an integer of 1 to 63) page, “MM” in a 3k page, or “UM” in a 3k+1 page and generalization thereof produces six patterns shown in FIG. 24 so that the write state of each word line WL can be estimated from 3-bit information “info”.

[Scheme C]

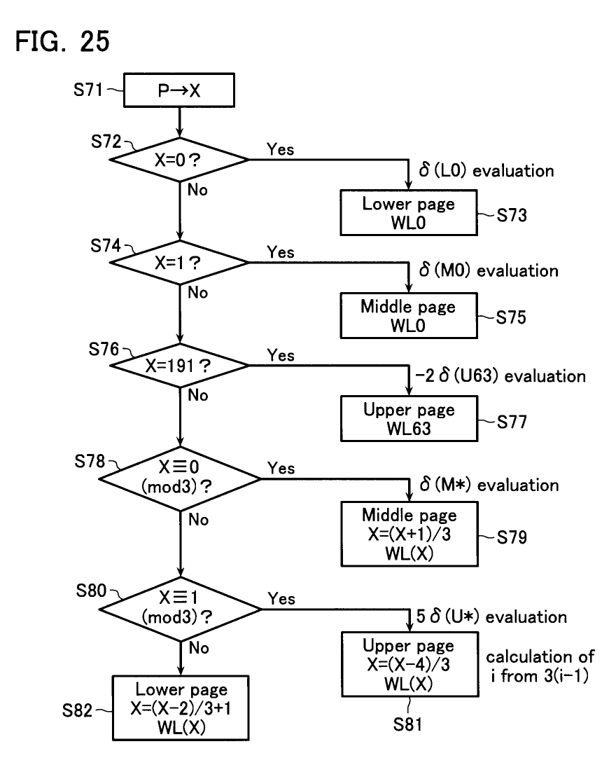

In Scheme C, the word line WLi corresponding to the access page address P and which page of L/U is accessed are determined. This processing is processing to determine the word line number and one of L/M/U page from the page addresses shown in FIG. 22. FIG. 25 is a flow chart showing this processing. First, the access page address P is substituted into the variable X (S71). Next, if X is “0”, the L page of the word line WL0 is set to be a page to be read, if X is “1”, the M page of the word line WL0, and if X is “191”, the U page of the word line WL63 (S72 to S77). If X is other than these values and if the remainder after dividing X by 3 is 0 (S78), the M page of the word line WL(X) of the number calculated by X=(X+1)/3 is set to be a page to be read (S79). If the remainder is 1 (S80), the U page of the word line WL(X) of the number calculated by X=(X−4)/3 is set to be a page to be read (S81). Further, if the remainder is 2 (S80), the L page of the word line WL(X) of the number calculated by X=(X−2)/3+1 is set to be a page to be read (S68).

[Scheme D]

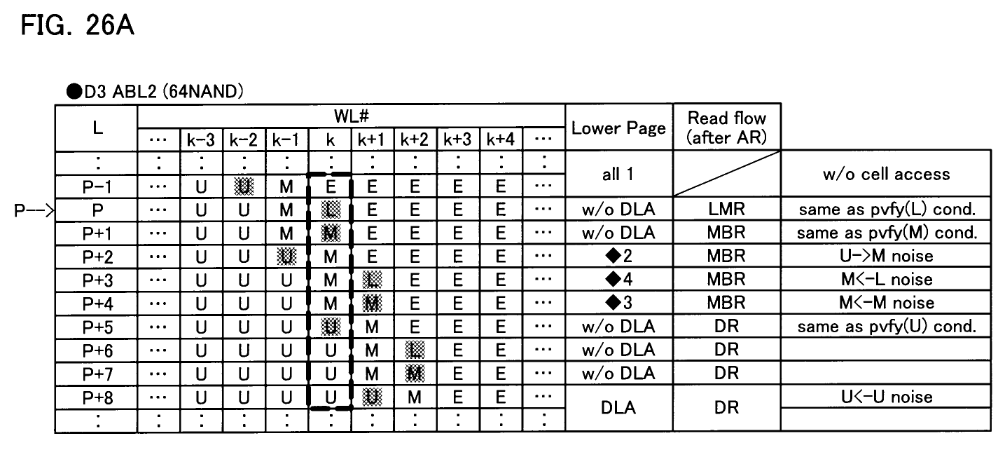

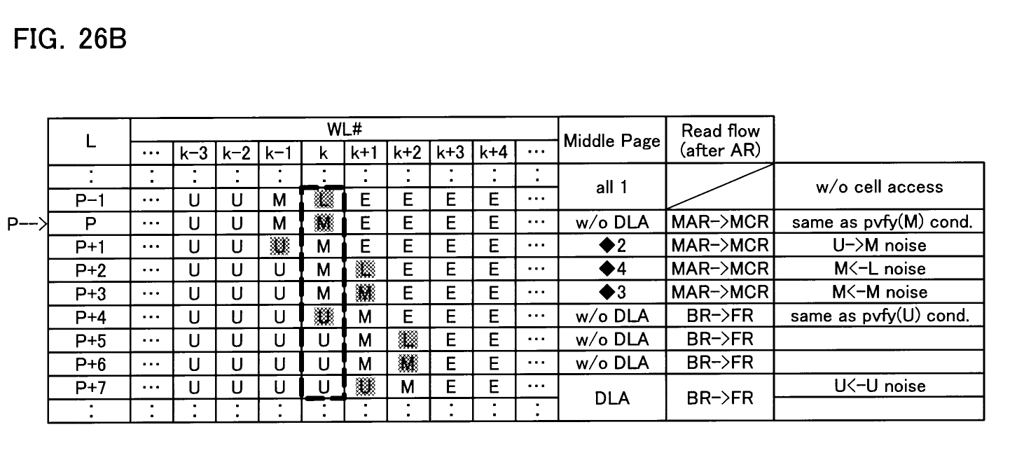

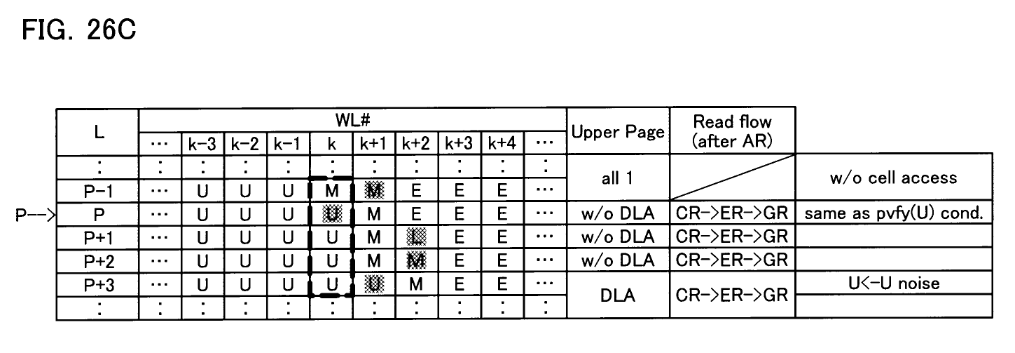

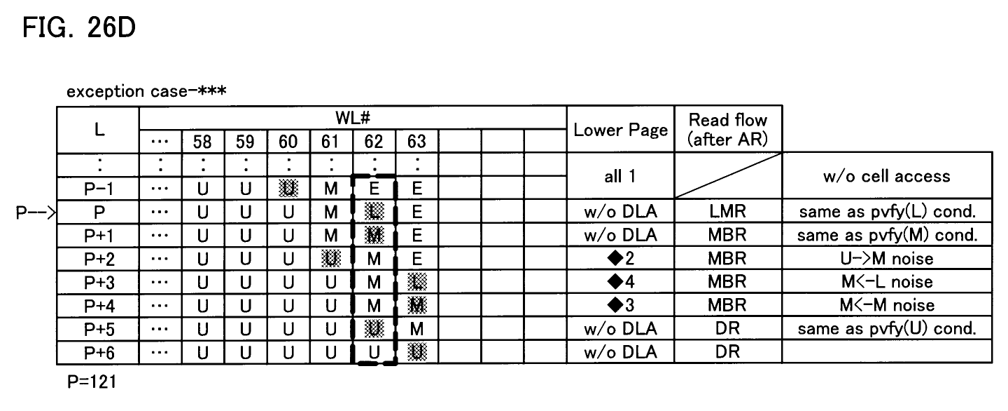

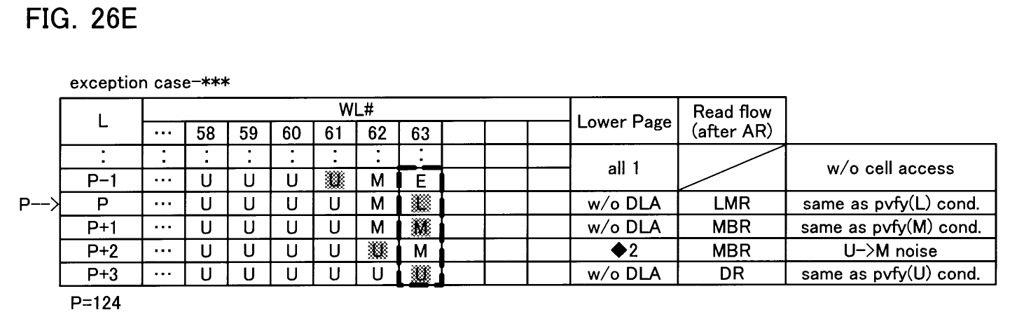

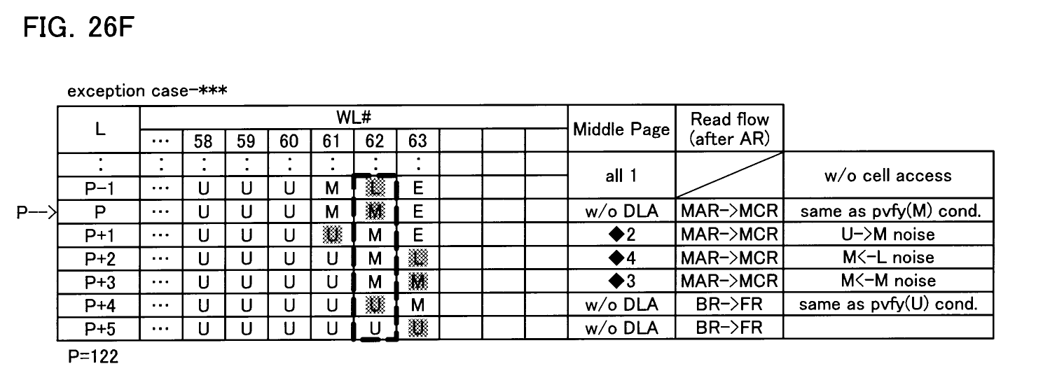

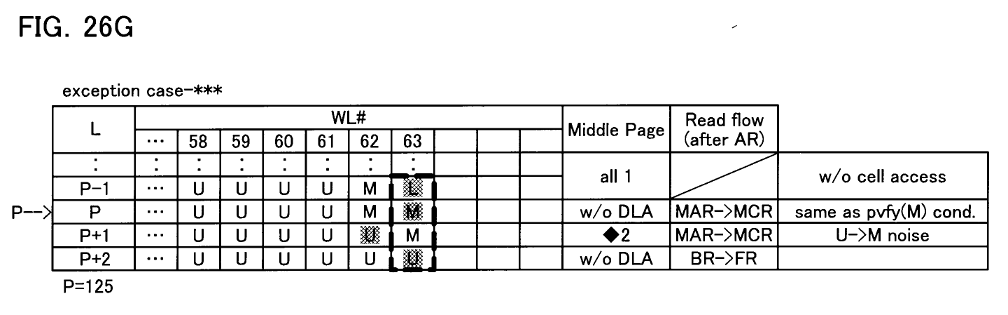

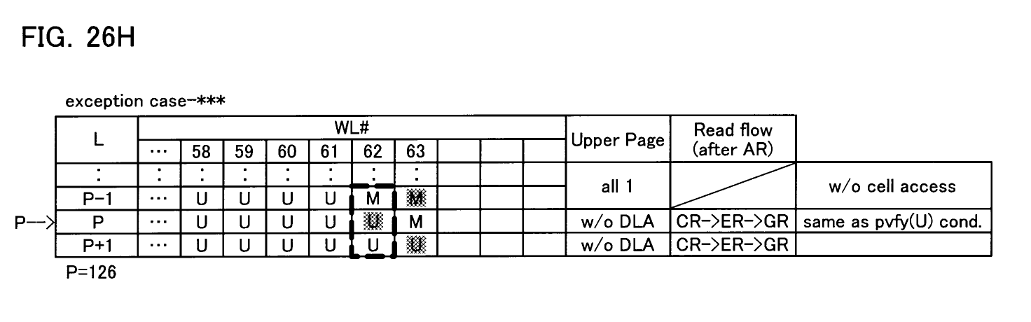

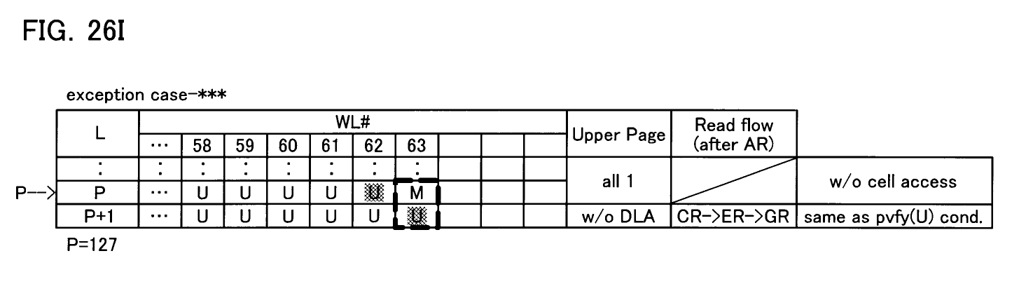

Next, in Scheme D, whether to read adjacent memory cells in advance in accordance with a difference between the access page address P and the last page address L and the read voltage Vread are determined. FIG. 26A to FIG. 26I are diagrams illustrating Scheme D.

FIG. 26A shows a case in which the L page of the word line WLk is read. ♦4 means that it is better to execute DLA if possible and the strength of necessity of DLA execution is: ♦2<♦4<♦3<DLA.

If, for example, the last page address L and the access page address P match, the word line WLk from which data is about to be read is the L page to which data is written lastly and since not susceptible to adjacent cells in this case, data is read by providing LMR in FIG. 16 to the word line WLk without executing DLA. If, on the other hand, the last page address L is one of P+2 to P+4, the threshold of the M page of the word line WLk is affected by writing of the U page of the word line WLk−1. Particularly if the last page address L is P+3 or P+4, the threshold of the M page of the word line WLk is affected by writing of the L page and the M page of the of the word line WLk+1, in addition to writing of the U page of the word line WLk−1. Therefore, ♦2 is attached to P+2, ♦4 to P+3, and ♦3 to P+4 in accordance with the affecting degree thereof. Further, if the last page address L is P+8 or greater, the threshold of the U page of the word line WLk is affected by writing of the U page of the word line WLk+1. Therefore, in this case, it is necessary to execute DLA during reading. The reading level provided to the word line WLk is the same as that in the third embodiment.

FIG. 26B shows a case in which the M page of the word line WLk is read. Also in this case, if the last page address L and the access page address P are equal, read processing of the page of the word line WLk from which data is about to be read is performed without executing DLA because of writing of the M page immediately before. If, on the other hand, the last page address L is one of P+1 to P+3, the U page of the word line WLk−1 affects the M page of the word line WLk from which data is about to be read. In this case, DLA is executed in accordance with a magnitude of influence thereof. If the last page address L is P+7 or greater, the threshold of the U page of the word line WLk is affected by writing of the U page of the word line WLk+1. Therefore, in this case, DLA is executed without fail during reading. The word line level during reading is the same as that in the third embodiment.

FIG. 26C shows a case in which the U page of the word line WLk is read. Also in this case, if the last page address L and the access page address P are equal, read processing of the page of the word line WLk from which data is about to be read is performed without executing DLA because of writing of the U page immediately before. If the last page address L is P+1 or P+2, DLA is not executed because the U page of the word line WLk is not affected. If, on the other hand, the last page address L is P+3 or greater, the U page of the word line WLk+1 affects the U page of the word line WLk from which data is about to be read. In this case, DLA is executed. Reading of the U page is the same as that in the third embodiment.

FIG. 26D to FIG. 26I are tables showing processing when data of end word lines is read and FIG. 26D shows L page reading of the word line WL62, FIG. 26E shows L page reading of the word line WL63, FIG. 26F shows M page reading of the word line WL62, FIG. 26G shows M page reading of the word line WL63, FIG. 26H shows U page reading of the word line WL62, and FIG. 26I shows U page reading of the word line WL63. Content thereof is similar to that described above and thus, a detailed description thereof is omitted.

The present invention is not limited to the above embodiments. In the above embodiments, for example, a NAND type flash memory is described, but the present invention can similarly be applied to other nonvolatile semiconductor memory devices such as a NOR type, DINOR (Divided bit line NOR) type, and ANT type EEPROM. In addition, the write state memory circuit is not limited to a nonvolatile semiconductor memory device and may be volatile memory circuit (for example, DRAM and SRAM).

What is claimed is:

1. A nonvolatile semiconductor memory device, comprising:
a memory cell array in which memory cells having an electrically rewritable charge accumulation layer are arranged;
a data writing/reading circuit that writes/reads data to/from the memory cell array in units of pages;
a write state information storage circuit for nonvolatile storage of write state information indicating a data write state to the memory cell array by the data writing/reading circuit; and
a control circuit that controls the data writing/reading circuit based on an access page address indicating a page from which data is about to be read by the data writing/reading circuit and write state information stored in the write state information storage circuit.

2. The nonvolatile semiconductor memory device according to claim 1, wherein
the control circuit distinguishes whether an access page determined by the access page address is in an erase state based on the write state information and, if the access page is in the erase state, controls the data writing/reading circuit so that data “1” is output as read data without the memory cell array being accessed.

3. The nonvolatile semiconductor memory device according to claim 1, wherein
the write state information includes a last page address indicating an address of a last page to which data is written lastly by the data writing/reading circuit and
the control circuit distinguishes whether an access page determined by the access page address is in an erase state based on the write state information and, if the access page is not in the erase state, estimates the data write state of the access page from the last page address and decides a read voltage of the data writing/reading circuit based on the estimated data write state of the access page.

4. The nonvolatile semiconductor memory device according to claim 3, wherein
if a lowest page is written to the access page and an upper page than the lowest page is not written to in pages adjacent to the access page, the control circuit controls the data writing/reading circuit so that the access page is read as it is.

5. The nonvolatile semiconductor memory device according to claim 3, wherein
if the access page is in a state immediately after an uppermost page being written, the control circuit controls the data writing/reading circuit so that the access page is read as it is.

6. The nonvolatile semiconductor memory device according to claim 3, wherein
if an uppermost page has been written to each of the access page and adjacent pages before and after the access page, the control circuit controls the data writing/reading circuit so that the uppermost pages in the adjacent pages to which data is written after the access page is read in advance and then, the access page is read based on readout results thereof.

7. The nonvolatile semiconductor memory device according to claim 1, wherein
the memory cell array has a plurality of word lines and a plurality of memory cells connected to one word line is defined as a page and
the data writing/reading circuit, which is used to write n-bit (n is an integer equal to 2 or greater) data to the memory cells, repeats a write operation of, after lower page being written to a page, writing a upper page than the lower page to a page corresponding to a word line to which data is written prior to a word line corresponding to the lower page and then, writing a lower page to a page of the next word line of the word line to which the lower page has been written.

8. The nonvolatile semiconductor memory device according to claim 1, wherein
a nonvolatile storage circuit is used as the write state information storage circuit.

9. A nonvolatile semiconductor memory device, comprising:
a memory cell array in which memory cells having an electrically rewritable charge accumulation layer are arranged;
a data writing/reading circuit that writes/reads data to/from the memory cell array in units of pages;
a write state information storage circuit for storing write state information indicating a data write state to the memory cell array by the data writing/reading circuit; and
a control circuit that references the write state information stored in the write state information storage circuit and, if an access page about to be read is a page to which data has been written and the data in the page is estimated to be affected by writing to adjacent pages after the data being written to the page, controls the data writing/reading circuit so that the access page is read after data of the adjacent pages being read.

10. The nonvolatile semiconductor memory device according to claim 9, wherein
if a lowest page is written to the access page and an upper page than the lowest page is not written to in pages adjacent to the access page, the control circuit controls the data writing/reading circuit so that the access page is read as it is.

11. The nonvolatile semiconductor memory device according to claim 9, wherein
if the access page is in a state immediately after an uppermost page being written, the control circuit controls the data writing/reading circuit so that the access page is read as it is.

12. The nonvolatile semiconductor memory device according to claim 9, wherein
if an uppermost page has been written to each of the access page and adjacent pages before and after the access page, the control circuit controls the data writing/reading circuit so that the uppermost pages in the adjacent pages to which data is written after the access page is read in advance and then, the access page is read based on readout results thereof.

13. The nonvolatile semiconductor memory device according to claim 9, wherein
the memory cell array has a plurality of word lines and a plurality of memory cells connected to one word line is defined as a page and
the data writing/reading circuit, which is used to write n-bit (n is an integer equal to 2 or greater) data to the memory cells, repeats a write operation of, after lower page being written to a page, writing a upper page than the lower page to a page corresponding to a word line to which data is written prior to a word line corresponding to the lower page and then, writing a lower page to a page of the next word line of the word line to which the lower page has been written.

14. The nonvolatile semiconductor memory device according to claim 9, wherein
the write state information includes a last page address indicating an address of a last page to which data is written lastly by the data writing/reading circuit and
the control circuit distinguishes whether the access page determined by the access page address is in an erase state based on the write state and, if the access page is not in the erase state, estimates the data write state of the access page from the last page address and decides a read voltage of the data writing/reading circuit based on the estimated data write state of the access page.

15. A nonvolatile semiconductor memory device, comprising:
a memory cell array in which memory cells having an electrically rewritable charge accumulation layer are arranged;
a data writing/reading circuit that writes/reads data to/from the memory cell array in units of pages;
a write state information storage circuit for storing write state information indicating a data write state to the memory cell array by the data writing/reading circuit; and
a control circuit that references the write state information stored in the write state information storage circuit and, if an access page about to be read is in an erase state, outputs data indicating the erase state as read data without the access page being accessed by the data writing/reading circuit.

16. The nonvolatile semiconductor memory device according to claim 15, wherein
if a lowest page is written to the access page and an upper page than the lowest page is not written to in pages adjacent to the access page, the control circuit controls the data writing/reading circuit so that the access page is read as it is.

17. The nonvolatile semiconductor memory device according to claim 15, wherein
if the access page is in a state immediately after an uppermost page being written, the control circuit controls the data writing/reading circuit so that the access page is read as it is.

18. The nonvolatile semiconductor memory device according to claim 15, wherein
if an uppermost page has been written to each of the access page and adjacent pages before and after the access page, the control circuit controls the data writing/reading circuit so that the uppermost pages in the adjacent pages to which data is written after the access page is read in advance and then, the access page is read based on readout results thereof.

19. The nonvolatile semiconductor memory device according to claim 15, wherein
the memory cell array has a plurality of word lines and a plurality of memory cells connected to one word line is defined as a page and
the data writing/reading circuit, which is used to write n-bit (n is an integer equal to 2 or greater) data to the memory cells, repeats a write operation of, after lower page being written to a page, writing a upper page than the lower page to a page corresponding to a word line to which data is written prior to a word line corresponding to the lower page and then, writing a lower page to a page of the next word line of the word line to which the lower page has been written.

20. The nonvolatile semiconductor memory device according to claim 15, wherein
the write state information includes a last page address indicating an address of a last page to which data is written lastly by the data writing/reading circuit and
the control circuit distinguishes whether the access page determined by the access page address is in an erase state based on the write state information and, if the access page is not in the erase state, estimates the data write state of the access page from the last page address and decides a read voltage of the data writing/reading circuit based on the estimated data write state of the access page.
